(19) United States
(12) Patent Application Publication
(10) Pub. No.: US 2016/0104843 A1
(43) Pub. Date: Apr. 14, 2016

(54) PHOTOELECTRIC CONVERSION ELEMENT AND SOLAR CELL

(71) Applicant: FUJIFILM Corporation, Tokyo (JP)

(72) Inventors: Katsumi KOBAYASHI, Ashigarakami-gun (JP); Hirotaka SATO, Ashigarakami-gun (JP)

(73) Assignee: FUJIFILM Corporation, Tokyo (JP)

(21) Appl. No.: 14/972,265

(22) Filed: Dec. 17, 2015

Related U.S. Application Data
(63) Continuation of application No. PCT/JP2014/069404, filed on Jul. 23, 2014.

(30) Foreign Application Priority Data
Jul. 31, 2013 (JP) 2013-159476
Jul. 8, 2014 (JP) 2014-140945
Jul. 17, 2014 (JP) 2014-147115

(51) Int. Cl. H01L 51/00; H01L 31/032

(52) U.S. Cl. CPC H01L 51/0059; H01L 31/0324; H01L 51/006; H01L 51/0061; H01L 51/0067; H01L 2031/0344

(57) ABSTRACT

A photoelectric conversion element including a first electrode which has a photosensitive layer containing a light absorber on a conductive support, a second electrode which is opposed to the first electrode, and a hole transport layer which is provided between the first electrode and the second electrode, in which the light absorber includes a compound having a perovskite crystal structure having a cation of a group I element of the periodic table or a cationic organic group, a cation of a metal atom M other than the group I elements of the periodic table, and an anion of an anionic atom X, and the hole transport layer contains a hole transport material of which the energy level of the highest occupied molecular orbital obtained by density functional theory calculation is within a range of −4.50 eV to −5.00 eV, and a solar cell including the photoelectric conversion element.

### CROSS-REFERENCE TO RELATED APPLICATIONS

This application is a Continuation of PCT International Application No. PCT/JP2014/69404, filed on Jul. 23, 2014, which claims priority under 35 U.S.C. §119(a) to Japanese Patent Application No. 2013-159476, filed on Jul. 31, 2013, Japanese Patent Application No. 2014-140945, filed on Jul. 8, 2014, and Japanese Patent Application No. 2014-147115, filed on Jul. 17, 2014. Each of the above application(s) is hereby expressly incorporated by reference, in its entirety, into the present application.

### BACKGROUND OF THE INVENTION

1. Field of the Invention

The present invention relates to a photoelectric conversion element and a solar cell, and particularly, to an organic and inorganic hybrid solid photoelectric conversion element and a solar cell using the organic and inorganic hybrid solid photoelectric conversion element.

2. Description of the Related Art

Photoelectric conversion elements are used in various optical sensors, copiers, solar cells, and the like. Regarding the photoelectric conversion elements, various types such as types using a metal, types using a semiconductor, types using an organic pigment or dye, or combination types thereof are put into practical use. Particularly, solar cells using inexhaustible solar energy are greatly expected to be put into real widespread use as cells which do not require a fuel and use unlimited clean energy.

Among solar cells, silicon-based solar cells, CIGS-based solar cells, which contain a compound including copper (Cu), indium (In), gallium (Ga), and selenium (Se), CdTe solar cells, which contain a compound including cadmium (Cd) and tellurium (Te), and the like have been put into widespread use due to policy considerations of countries. However, in order to put the solar cells into widespread use to a level at which the cells replace thermal power generation or nuclear power generation, a further reduction in the manufacturing cost is desired.

Dye-sensitized solar cells and organic thin-film solar cells are expected as next-generation solar cells and are intensively considered since a vacuum process is not used in the manufacturing of the cells and there is a possibility of a significant reduction in the manufacturing cost by an application process. However, it cannot be said that dye-sensitized solar cells and organic thin-film solar cells have sufficient photoelectric conversion efficiency.

Recently, solar cells in which a lead complex having a perovskite crystal structure as a light absorber of a photosensitive layer and an electrolyte are combined have been proposed (see KR10-1172374B and J. Am. Chem. Soc., 2009, 131 (17), 6050-6051). Thereafter, solar cells using this lead complex have been reported to be manufactured through an application process and to exhibit photoelectric conversion efficiency that is equal to or higher than those of dye-sensitized solar cells and organic thin-film solar cells (for example, see Science, 338, 643 (2012) or Nature Photonics Published Online, 5, May, 2013), and have attracted attention.

### SUMMARY OF THE INVENTION

According to the examination of the inventors of the invention, solar cells using a compound having a perovskite crystal structure are found to require a further improvement in the photoelectric conversion efficiency, compared to solar cells using an inorganic silicon.

In addition to this, the solar cells using a compound having a perovskite crystal structure are found to have a problem in which the obtained photoelectric conversion elements or solar cells do not have stable performance, that is, the same performance is not obtained even when the photoelectric conversion elements or solar cells are manufactured in the same manner.

Accordingly, an object of the invention is to provide a photoelectric conversion element and a solar cell which have improved photoelectric conversion efficiency and which exhibit stable cell performance such as photoelectric conversion efficiency even when being repeatedly manufactured.

The inventors of the invention have focused on the molecular structure and the properties of the material used in a hole transport layer in a solar cell using a compound having a perovskite crystal structure, and as a result of the examination, have obtained a clue for solving the object and completed the invention.

That is, the object is solved by the following means.

<1> A photoelectric conversion element including a first electrode which has a photosensitive layer containing a light absorber on a conductive support, a second electrode which is opposed to the first electrode, and a hole transport layer which is provided between the first electrode and the second electrode, in which the light absorber includes a compound having a perovskite crystal structure having a cation of a group I element of the periodic table or a cation of a cationic organic group A, a cation of a metal atom M other than the group I elements of the periodic table, and an anion of an anionic atom X, and the hole transport layer contains a hole transport material of which the energy level of the highest occupied molecular orbital obtained by density functional theory calculation is within a range of −4.50 eV to −5.00 eV.

<2> The photoelectric conversion element according to <1>, in which the hole transport material is represented by the following Formula (D).

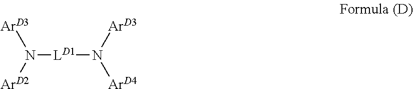

In Formula (D), L^{D1} indicates a linking group in which at least two of arylene groups and heteroarylene groups are combined, an arylene group, or a heteroarylene group, each of Ar^{D1} to Ar^{D4} independently indicates an aryl group or a heteroaryl group, Ar^{D1} to Ar^{D4} may have a substituent, and Ar^{D1} and Ar^{D2} may be bonded to each other to form a ring, and Ar^{D3} and Ar^{D4} may be bonded to each other to form a ring.

<3> The photoelectric conversion element according to <2>, in which at least one of Ar^{D1} to Ar^{D4} has a substituent, and the substituent is 1) an alkyl group, an alkoxy group, an alkylthio group, an alkylamino group, a dialkylamino group, an alkoxycarbonyl group, an alkylsilyl group, or an acyl group, which has two or more carbon atoms, or 2) an aryl group or a heteroaryl group substituted with the group described in 1).

<4> The photoelectric conversion element according to <2> or <3>, in which at least one of Ar^{D1} to Ar^{D4} has a substituent, and the substituent is an alkyl group having two or more carbon atoms, an alkoxy group having two or more carbon atoms, an aryl group substituted with an alkyl group having two or more carbon atoms, an aryl group substituted with an alkoxy group having two or more carbon atoms, a heteroaryl group substituted with an alkyl group having two or more carbon atoms, or a heteroaryl group substituted with an alkoxy group having two or more carbon atoms.

<5> The photoelectric conversion element according to any one of <2> to <4>, in which L^{D1} is represented by any one of the following Formulae (L-1) to (L-4).

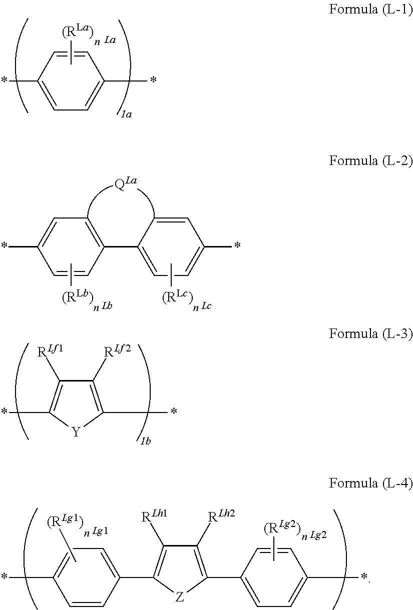

In the formulae, each of Y and Z independently indicates O, S, or —CH═N—, each of R^{La} to R^{Lc}, R^{Lg1} and R^{Lg2} independently indicates a substituent, each of R^{Lf1}, R^{Lf2}, R^{Lh1}, and R^{Lh2} independently indicates a hydrogen atom or a substituent, each of n^{La}, n^{Lg1}, and n^{Lg2} independently indicates an integer of 0 to 4, each of n^{Lb} and n^{Lc} independently indicates an integer of 0 to 3, each of la and lb independently indicates an integer of 1 to 4, Q^{La} indicates a group which forms a saturated hydrocarbon ring or a spiro ring of a five-membered ring or a six-membered ring, or —Si(Rx)(Ry)-, each of Rx and Ry independently indicates an alkyl group, and * indicates a bonding position with N of Formula (D).

<6> The photoelectric conversion element according to any one of <2> to <5>, in which the hole transport material is represented by any one of the following Formulae (D-1) to (D-4).

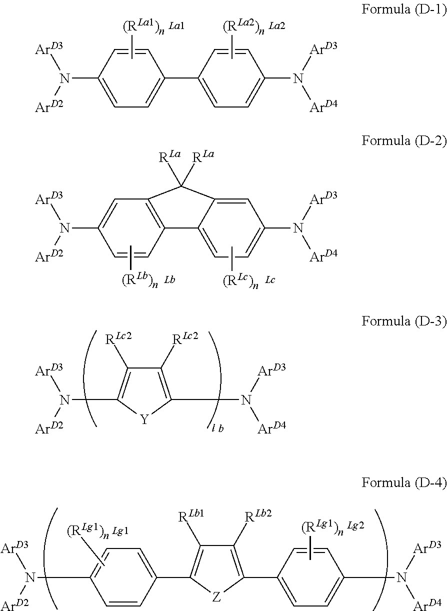

In the formulae, each of Y and Z independently indicates O, S, or —CH═N—, lb indicates an integer of 1 to 4, Ar^{D1} to Ar^{D4} are synonymous with Ar^{D1} to Ar^{D4} of Formula (D), each of R^{La1}, R^{La2}, R^{Lb}, R^{Lc}, R^{Lg1}, and R^{Lg2} independently indicates a substituent, each of R^{Lf1}, R^{Lf2}, R^{Lh1}, and R^{Lh2} independently indicates a hydrogen atom or a substituent, each of n^{La1}, n^{La2}, n^{Lg1}, and n^{Lg2} independently indicates an integer of 0 to 4, each of n^{Lb} and n^{Lc} independently indicates an integer of 0 to 3, each of R^{Ld} and R^{Le} independently indicates an alkyl group, and R^{Ld} and R^{Le} may be bonded to each other to form a ring.

<7> The photoelectric conversion element according to any one of <2> to <6>, in which Ar^{D1} is represented by any one of the following Formulae (R-1) to (R-3).

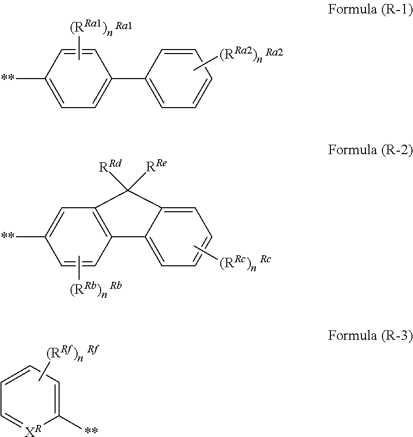

In the formulae, X^{R} indicates CH or N, each of R^{Ra1}, R^{Ra2}, R^{Rb}, R^{Rc}, and R^{Rf} independently indicates a substituent, each of n^{Ra1}, n^{Rc}, and n^{Rf} independently indicates an integer of 0 to 4, n^{Ra2} indicates an integer of 0 to 5, n^{Rb} indicates an integer of 0 to 3, each of R^{Rd} and R^{Re} independently indicates an alkyl group, R^{Rd} and R^{Re} may be bonded to each other to form a ring, and ** indicates a bonding position with N in any one of Formulae (D) and (D-1) to (D-4).

<8> The photoelectric conversion element according to any one of <1> to <7>, in which the energy level of the highest occupied molecular orbital is within a range of −4.60 eV to −4.80 eV.

<9> The photoelectric conversion element according to any one of <1> to <8>, in which the compound having a perovskite crystal structure is a compound represented by the following Formula (I).

AₐMₘXₓ Formula (I):

In Formula (I), A indicates a group I element of the periodic table or a cationic organic group, M indicates a metal atom other than the group I elements of the periodic table, X indicates an anionic atom, a indicates 1 or 2, m indicates 1, and a, m, and x satisfy a+2m=x.

<10> The photoelectric conversion element according to any one of <1> to <9>, in which the compound having a perovskite crystal structure includes a compound represented by the following Formula (I-1).

AMX₃ Formula (I-1):

In Formula (I-1), A indicates a group I element of the periodic table or a cationic organic group, M indicates a metal atom other than the group I elements of the periodic table, and X indicates an anionic atom.

<11> The photoelectric conversion element according to any one of <1> to <10>, in which the compound having a perovskite crystal structure includes a compound represented by the following Formula (I-2).

A₂MX₄ Formula (I-2):

In Formula (I-2), A indicates a group I element of the periodic table or a cationic organic group, M indicates a metal atom other than the group I elements of the periodic table, and X indicates an anionic atom.

<12> The photoelectric conversion element according to any one of <1> to <11>, in which A is represented by the following Formula (1).

R^{1a}—NH₃ Formula (1):

In Formula (1), R^{1a} indicates a substituent.

<13> The photoelectric conversion element according to <12>, in which R^{1a} is an alkyl group, a cycloalkyl group, an alkenyl group, an alkynyl group, an aryl group, a heteroaryl group, or a group represented by the following Formula (2).

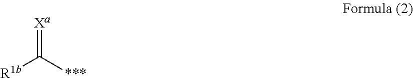

In Formula (2), X^{a} indicates NR^{1c}, an oxygen atom, or a sulfur atom, each of R^{1b} and R^{1c} independently indicates a hydrogen atom or a substituent, and *** indicates a bonding position with N of Formula (1).

<14> The photoelectric conversion element according to any one of <1> to <13>, in which X is a halogen atom.

<15> The photoelectric conversion element according to any one of <1> to <14>, in which M is Pb or Sn.

<16> The photoelectric conversion element according to any one of <1> to <15>, further including a porous layer which is between the conductive support and the photosensitive layer.

<17> A solar cell including the photoelectric conversion element according to any one of <1> to <16>.

In this description, the respective formulae, particularly, Formulae (I-1), (I-2), (1), (2), and (A^{am}) may be partially represented as rational formulae in order to understand the chemical structure of the compound having a perovskite crystal structure. With this, partial structures are called groups, substituents, atoms, or the like in the respective formulae, but in this description, these mean element groups or elements constituting the (substituent) groups represented by the above formulae.

In this description, regarding expression of compounds (including complex and dye), the compounds are used to mean not only the compounds themselves, but also salts and ions thereof. These also include compounds having a structure partially modified within the scope of causing target effects. Regarding compounds having no specification about substitution or unsubstitution, these mean compounds including compounds having an arbitrary substituent within the scope of causing desired effects. This is also applied to the cases of the substituent and the linking group (hereinafter, referred to as substituent and the like).

In this description, when there are more than one substituent and the like indicated by a specific reference, or when a plurality of substituents and the like are simultaneously specified, the respective substituents and the like may be the same as or different from each other unless otherwise mentioned. This is also applied to the case of the specification of the number of substituents and the like. In addition, when a plurality of substituents and the like are close to each other (particularly, adjacent to each other), these may be connected to each other and form a ring unless otherwise mentioned. In addition, rings such as an aliphatic ring, an aromatic ring, and a hetero ring may be condensed and form a condensed ring.

In this description, the numerical value range represented using “to” means a range including the numerical values described before and after “to” as a lower limit value and an upper limit value.

According to the invention, it is possible to provide a photoelectric conversion element and a solar cell which have improved photoelectric conversion efficiency and which exhibit stable cell performance such as photoelectric conversion efficiency even when being repeatedly manufactured.

### BRIEF DESCRIPTION OF THE DRAWINGS

FIG. 1 is a cross-sectional view schematically showing a preferred aspect of a photoelectric conversion element of the invention.

FIG. 2 is a cross-sectional view schematically showing a preferred aspect in which the photoelectric conversion element of the invention has a thick photosensitive layer.

FIG. 3 is a cross-sectional view schematically showing another preferred aspect of the photoelectric conversion element of the invention.

FIGS. 4A, 4B, and 4C illustrate a crystal structure of a compound having a perovskite crystal structure.

### DESCRIPTION OF THE PREFERRED EMBODIMENTS

<<Photoelectric Conversion Element>>

A photoelectric conversion element of the invention has a first electrode having a conductive support and a photosensitive layer containing a light absorber, a second electrode opposed to the first electrode, and a hole transport layer provided between the first electrode and the second electrode. The photosensitive layer, the hole transport layer, and the second electrode are provided on the conductive support in this order.

The light absorber includes at least one type of compound having a perovskite crystal structure (hereinafter, may be referred to as perovskite compound) to be described later. The light absorber may include a light absorber other than the perovskite compound together with the perovskite compound. Examples of the light absorber other than the perovskite compound include metal complex dyes and organic dyes.

The hole transport layer contains at least one type of hole transport material of which the energy level of the highest occupied molecular orbital (HOMO) is within a range of −4.50 eV to −5.00 eV. The hole transport layer may contain, together with this hole transport material, a hole transport material of which the energy level of the HOMO is out of the range of −4.50 eV to −5.00 eV.

In the invention, a photoelectric conversion element including a perovskite compound as a light absorber and having a solid hole transport material layer is referred to as an organic and inorganic hybrid solid photoelectric conversion element.

In the invention, the expression “having a photosensitive layer . . . on a conductive support” has a meaning including an aspect in which the photosensitive layer is provided in contact with a surface of the conductive support and an aspect in which the photosensitive layer is provided over the surface of the conductive support with other layers interposed therebetween.

In the aspect in which the photosensitive layer is provided over the surface of the conductive support with other layers interposed therebetween, other layers provided between the conductive support and the photosensitive layer are not particularly limited as long as these do not reduce cell performance of a solar cell. Examples thereof include a porous layer and a blocking layer.

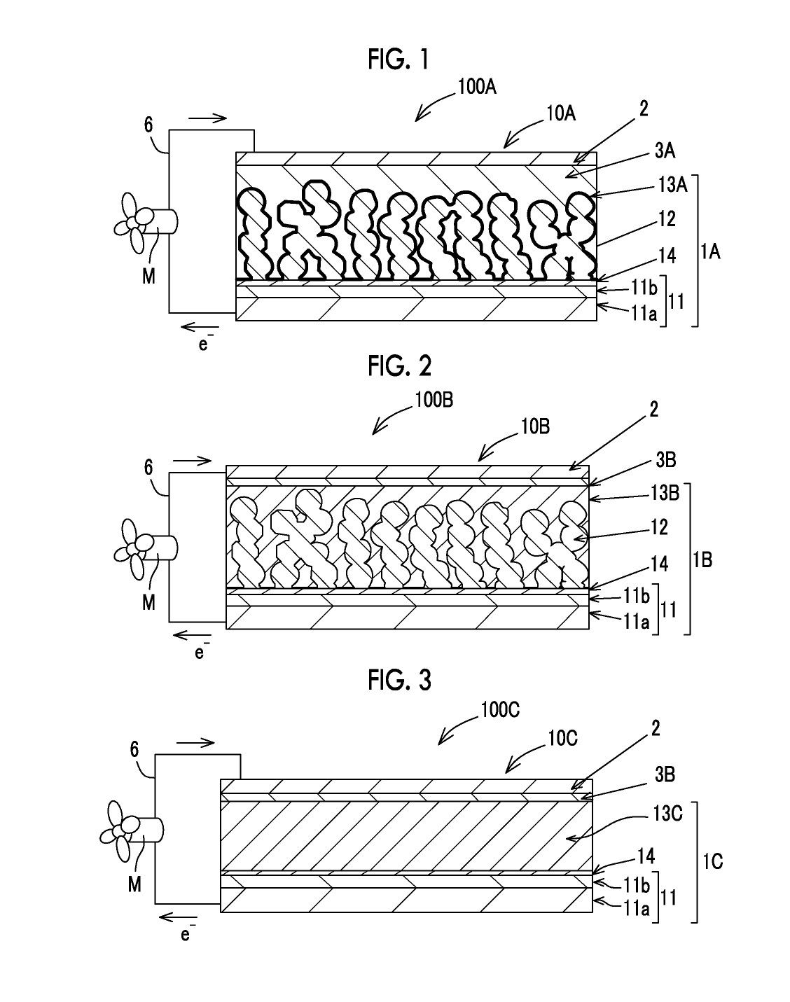

In the invention, examples of the aspect in which the photosensitive layer is provided over the surface of the conductive support with other layers interposed therebetween include an aspect in which the photosensitive layer is provided in a thin film shape or the like on a surface of a porous layer (see FIG. 1), an aspect in which the photosensitive layer is provided to have a large thickness on a surface of a porous layer (see FIG. 2), an aspect in which the photosensitive layer is provided to have a small thickness on a surface of a blocking layer, and an aspect in which the photosensitive layer is provided to have a large thickness on a surface of a blocking layer (see FIG. 3). The photosensitive layer may be provided in a linear or dispersed shape, and preferably in a film shape.

The configurations of the photoelectric conversion element of the invention, other than the configurations specified in the invention, are not particularly limited, and known configurations related to the photoelectric conversion element and the solar cell can be employed. The respective layers constituting the photoelectric conversion element of the invention are designed according to the purpose, and may be formed into either a single layer or a multi-layer.

Hereinafter, preferred aspects of the photoelectric conversion element of the invention will be described.

In FIGS. 1 to 3, the same references indicate the same constituent elements (members).

FIGS. 1 and 2 show the size of fine particles which form the porous layer in an emphasized manner. These fine particles are preferably stuck in a horizontal direction and in a vertical direction relative to the conductive support to form a porous structure.

In this description, when simply using the expression “photoelectric conversion element 10”, it means photoelectric conversion elements 10A, 10B, and 10C unless otherwise mentioned. This is also applied to the cases of system 100, first electrode 1, and photosensitive layer 13. When simply using the expression “hole transport layer 3”, it means hole transport layers 3A and 3B unless otherwise mentioned.

As a preferred aspect of the photoelectric conversion element of the invention, a photoelectric conversion element 10A shown in FIG. 1 can be exemplified. A system 100A shown in FIG. 1 is a system in which the photoelectric conversion element 10A is applied for use in a cell to make operation means M (for example, electric motor) work by an external circuit 6.

This photoelectric conversion element 10A has a first electrode 1A, a second electrode 2, and a hole transport layer 3A containing a hole transport material to be described later between the first electrode 1A and the second electrode 2.

The first electrode 1A has a conductive support 11 formed of a support 11a and a transparent electrode 11b, and a photosensitive layer 13A. It is preferable that the first electrode 1A has a porous layer 12. It is preferable that a blocking layer 14 is provided on the transparent electrode 11b and the porous layer 12 is formed on the blocking layer 14.

A photoelectric conversion element 10B shown in FIG. 2 schematically shows a preferred aspect in which the photosensitive layer 13A of the photoelectric conversion element 10A shown in FIG. 1 is provided to have a large thickness. In this photoelectric conversion element 10B, a hole transport layer 3B is provided to have a small thickness. The photoelectric conversion element 10B is different from the photoelectric conversion element 10A shown in FIG. 1 in terms of the thicknesses of the photosensitive layer 13B and the hole transport layer 3B, but except for this, the photoelectric conversion element 10B has the same configuration as the photoelectric conversion element 10A.

A photoelectric conversion element 10C shown in FIG. 3 schematically shows another preferred aspect of the photoelectric conversion element of the invention. The photoelectric conversion element 10C is different from the photoelectric conversion element 10B shown in FIG. 2 in terms of the fact that no porous layer 12 is provided, but except for this, the photoelectric conversion element 10C has the same configuration as the photoelectric conversion element 10B. That is, in the photoelectric conversion element 10C, a photosensitive layer 13C is formed on the surface of the blocking layer 14.

In the invention, the system 100 applying the photoelectric conversion element 10 functions as a solar cell as follows.

That is, in the photoelectric conversion element 10, the light transmitted through the conductive support 11 or the second electrode 2 and entering the photosensitive layer 13 excites the light absorber. The excited light absorber has high-energy electrons, and the electrons reach the conductive support 11 from the photosensitive layer 13. At this time, the light absorber emitting the high-energy electrons becomes an oxidant. The electrons reaching the conductive support 11 return to the photosensitive layer 13 through the second electrode 2 and the hole transport layer 3 while working in the external circuit 6. The light absorber is reduced by the electrons returning to the photosensitive layer 13. The system 100 functions as a solar cell by repeating the excitation of the light absorber and the movement of the electrons.

The flow of the electrons from the photosensitive layer 13 to the conductive support 11 varies with the presence or absence and the type of the porous layer 12. In the photoelectric conversion element 10, electronic conduction occurs in which electrons move between perovskite compounds. Accordingly, when providing the porous layer 12, the porous layer 12 can be formed of an insulator other than a conventional semiconductor. When the porous layer 12 is formed of a semiconductor, electronic conduction occurs in which electrons move in or between semiconductor particles of the porous layer 12. When the porous layer 12 is formed of an insulator, no electronic conduction occurs in the porous layer 12. When the porous layer 12 is formed of an insulator, a relatively high electromotive force (Voc) is obtained when fine particles of an aluminum oxide (Al₂O₃) are used as insulator fine particles.

Electronic conduction also occurs in the blocking layer 14 when the blocking layer 14 as one of the above-described other layers is formed of a conductor or a semiconductor.

The photoelectric conversion element and the solar cell of the invention are not limited to the preferred aspects, and the configurations and the like of the respective aspects can be appropriately combined between the aspects without departing from the gist of the invention.

In the invention, except for the light absorber and the hole transport layer 3, the materials and the members used in the photoelectric conversion element or the solar cell can be prepared through usual methods. For example, KR10-1172374B, J. Am. Chem. Soc., 2009, 131 (17), 6050-6051, Science, 338, 643 (2012), and Nature Photonics Published Online, 5, May, 2013 can be referred to regarding a photoelectric conversion element or a solar cell using a perovskite compound. In addition, for example, JP2001-291534A, U.S. Pat. No. 4,927,721A, U.S. Pat. No. 4,684,537A, U.S. Pat. No. 5,084,365A, U.S. Pat. No. 5,350,644A, U.S. Pat. No. 5,463,057A, U.S. Pat. No. 5,525,440A, JP1995-249790A (JP-H7-249790A), JP2004-220974A, and JP2008-135197A can be referred to regarding a dye-sensitized solar cell.

Hereinafter, preferred aspects of main members and compounds of the photoelectric conversion element and the solar cell of the invention will be described.

<First Electrode 1>

The first electrode 1 has the conductive support 11 and the photosensitive layer 13, and functions as a working electrode in the photoelectric conversion element 10.

The first electrode 1 preferably has one or both of the porous layer 12 and the blocking layer 14, and more preferably has at least the blocking layer 14.

—Conductive Support 11—

The conductive support 11 is not particularly limited as long as it has conductive properties and can support the photosensitive layer 13 and the like. The conductive support 11 is preferably made of a conductive material such as a metal, or preferably configured to have a glass or plastic support 11a and a transparent electrode 11b as a conductive film formed on a surface of the support 11a.

Among these, a conductive support 11 in which a transparent electrode 11b is formed by coating a surface of a glass or plastic support 11a with a conductive metal oxide as shown in FIGS. 1 to 3 is more preferred. Examples of the plastic support 11a include transparent polymer films described in paragraph 0153 of JP2001-291534A. As the material which forms the support 11a, ceramics (JP2005-135902A) or a conductive resin (JP2001-160425A) can be used other than glass and plastic. As the metal oxide, a tin oxide (TO) is preferred, and an indium-tin oxide (tin-doped indium oxide; ITO) and a fluorine-doped tin oxide such as a tin oxide doped with fluorine (FTO) are particularly preferred. At this time, the amount of the metal oxide applied is preferably 0.1 g to 100 g per surface area of 1 m² of the support 11a. When using the conductive support 11, light preferably enters from the side of the support 11a.

The conductive support 11 is preferably substantially transparent. In the invention, the expression “substantially transparent” means that the transmittance of light (wavelength: 300 nm to 1200 nm) is 10% or greater, and the transmittance is preferably 50% or greater, and particularly preferably 80% or greater.

The thicknesses of the support 11a and the conductive support 11 are not particularly limited and are set to appropriate thicknesses. For example, the thicknesses are preferably 0.01 μm to 10 mm, more preferably 0.1 μm to 5 mm, and particularly preferably 0.3 μm to 4 mm.

When providing the transparent electrode 11b, the thickness of the transparent electrode 11b is not particularly limited. For example, the thickness is preferably 0.01 μm to 30 μm, more preferably 0.03 μm to 25 μm, and particularly preferably 0.05 μm to 20 μm.

The surface of the conductive support 11 or the support 11a may have a light management function. For example, an anti-reflection film described in JP2003-123859A, obtained by alternately laminating a high-refraction film and an oxide film having a low refractive index, may be provided on the surface of the conductive support 11 or the support 11a, or a light guide function described in JP2002-260746A may be imparted thereto.

—Blocking Layer 14—

In the invention, the blocking layer 14 is preferably provided on a surface of the transparent electrode 11b, that is, between the conductive support 11 and the porous layer 12 or the hole transport layer 3.

In the photoelectric conversion element and the solar cell, when the hole transport layer 3 and the transparent electrode 11b are brought into direct contact with each other, a reverse current is generated. The blocking layer 14 functions to prevent the reverse current. The blocking layer 14 is also called a short circuit prevention layer.

The material which forms the blocking layer 14 is not particularly limited as long as it is a material capable of serving the above-described function. However, the material is preferably a visible light transmissive substance having insulating properties with respect to the conductive support 11 (transparent electrode 11b). Specifically, the “substance having insulating properties with respect to the conductive support 11 (transparent electrode 11b)” indicates a compound (n-type semiconductor compound) having a conduction band energy level that is not lower than that of the material which forms the conductive support 11 (a metal oxide which forms the transparent electrode 11b) and is lower than those of the material which forms the porous layer 12 and the light absorber in a ground state.

Examples of the material which forms the blocking layer 14 include silicon oxide, magnesium oxide, aluminum oxide, calcium carbonate, polyvinyl alcohol, and polyurethane. In addition, the material may be a material which is usually used as a photoelectric conversion material, and examples thereof include titanium oxide, tin oxide, niobium oxide, and tungsten oxide. Among these, titanium oxide, tin oxide, magnesium oxide, aluminum oxide, and the like are preferred.

The thickness of the blocking layer 14 is preferably 0.001 μm to 10 μm, more preferably 0.005 μm to 1 μm, and particularly preferably 0.01 μm to 0.1 μm.

—Porous Layer 12—

In the invention, the porous layer 12 is preferably provided on the transparent electrode 11b. When the blocking layer 14 is provided, the porous layer 12 is formed on the blocking layer 14.

The porous layer 12 is a layer functioning as a foundation to carry the photosensitive layer 13 on the surface thereof. In the solar cell, in order to increase the light absorption efficiency, the surface area of at least a part which receives light such as solar light is preferably increased, and the entire surface area of the porous layer 12 is more preferably increased.

The porous layer 12 is preferably a fine particle layer with pores, which is formed by accumulating or firmly adhering fine particles of the material which forms the porous layer 12. The porous layer 12 may be a fine particle layer which is formed by accumulating two or more types of multi-fine particles. When the porous layer 12 is a fine particle layer with pores, the amount of the light absorber carried (adsorbed) can be increased.

The surface areas of the respective fine particles constituting the porous layer 12 are preferably increased to increase the surface area of the porous layer 12. In the invention, in a state in which the conductive support 11 or the like is coated with fine particles which form the porous layer 12, the surface area of the fine particles is preferably 10 or more times, and more preferably 100 or more times the projected area. The upper limit thereof is not particularly limited, but generally about 5000 times. The particle diameter of the fine particles which form the porous layer 12 is preferably 0.001 μm to 1 μm as primary particles in terms of the average particle diameter using a diameter when the projected area is converted into a circle. When the porous layer 12 is formed using a dispersion of fine particles, the average particle diameter of the fine particles is preferably 0.01 μm to 100 μm in terms of the average particle diameter of the dispersion.

The material which forms the porous layer 12 is not particularly limited in terms of the conductive properties. The material may be an insulator (insulating material), or a conductive material or semiconductor (semiconductive material).

As the material which forms the porous layer 12, a chalcogenide (for example, oxide, sulfide, selenide, and the like) of a metal, a compound having a perovskite crystal structure (except for light absorber to be described later), a silicon oxide (for example, silicon dioxide and zeolite), or a carbon nano-tube (including carbon nano-wire, carbon nano-rod, and the like) can be used.

The chalcogenide of a metal is not particularly limited, and preferred examples thereof include an oxide of titanium, tin, zinc, tungsten, zirconium, hafnium, strontium, indium, cerium, yttrium, lanthanum, vanadium, niobium, aluminum, or tantalum, cadmium sulfide, and cadmium selenide. Examples of the crystal structure of the chalcogenide of a metal include an anatase type, a brookite type, and a rutile type, and an anatase type and a brookite type are preferred.

The compound having a perovskite crystal structure is not particularly limited, and examples thereof include a transition metal oxide. Examples thereof include strontium titanate, calcium titanate, barium titanate, lead titanate, barium zirconate, barium stannate, lead zirconate, strontium zirconate, strontium tantalate, potassium niobate, bismuth ferrate, strontium barium titanate, barium lanthanum titanate, calcium titanate, sodium titanate, and bismuth titanate. Among these, strontium titanate, calcium titanate, and the like are preferred.

The carbon nano-tube has a shape in which a carbon film (graphene sheet) is wound into a cylindrical shape. The carbon nano-tube is classified into a single-layer carbon nano-tube (SWCNT) in which one graphene sheet is wound into a cylindrical shape, a double-layer carbon nano-tube (DWCNT) in which two graphene sheets are concentrically wound, and a multi-layer carbon nano-tube (MWCNT) in which a plurality of graphene sheets are concentrically wound. As the porous layer 12, any carbon nano-tube can be used with no particular limits.

Among these, an oxide of titanium, tin, zinc, zirconium, aluminum, or silicon, or a carbon nano-tube is preferred, and a titanium oxide or an aluminum oxide is more preferred as the material which forms the porous layer 12.

The porous layer 12 may be formed of at least one or two or more of the above-described chalcogenide of a metal, compound having a perovskite crystal structure, oxide of silicon, and carbon nano-tube.

As will be described later, the material which forms the porous layer 12 is preferably used as fine particles. Regarding the material which forms the porous layer 12, a nano-tube, nano-wire, or nano-rod of a chalcogenide of a metal, a compound having a perovskite crystal structure, and an oxide of silicon may be used with fine particles of a chalcogenide of a metal, a compound having a perovskite crystal structure, an oxide of silicon, and a carbon nano-tube.

The thickness of the porous layer 12 is not particularly limited, but usually within a range of 0.1 μm to 100 μm. When the photoelectric conversion element is used as a solar cell, the thickness is preferably 0.1 μm to 50 μm, and more preferably 0.3 μm to 30 μm.

The thickness of the porous layer 12 is specified by an average distance from the surface of the underlying layer on which the porous layer 12 is formed to the surface of the porous layer 12 along a linear direction intersecting at an angle of 90° relative to the surface of the conductive support 11 in a cross-section of the photoelectric conversion element 10. Here, the “surface of the underlying layer on which the porous layer 12 is formed” means an interface between the conductive support 11 and the porous layer 12. When other layers such as the blocking layer 14 are formed between the conductive support 11 and the porous layer 12, the above expression means an interface between the above other layers and the porous layer 12. In addition, the “surface of the porous layer 12” is, on a virtual straight line intersecting at an angle of 90° relative to the surface of the conductive support 11, a point of the porous layer 12 positioned closest to the side of the second electrode 2 from the conductive support 11 (intersection point between the virtual straight line and the outline of the porous layer 12). The “average distance” means an average of ten farthest distances, each of which is obtained by obtaining a farthest distance from the surface of the underlying layer to the surface of the porous layer 12 for each of ten parts obtained by equally dividing a specific observation region in a cross-section of the photoelectric conversion element 10 into ten along a direction (horizontal direction in FIGS. 1 to 3) horizontal to (parallel to) the surface of the conductive support 11. The thickness of the porous layer 12 can be measured by observing the cross-section of the photoelectric conversion element 10 with a scanning electron microscope (SEM).

Unless otherwise mentioned, thicknesses of other layers such as the blocking layer 14 can also be measured in the same manner.

—Photosensitive Layer (Light Absorption Layer) 13—

The photosensitive layer 13 is provided on the surface (when this surface has irregularities, interior surfaces thereof are included) of the porous layer 12 (photoelectric conversion elements 10A and 10B) or the blocking layer 14 (photoelectric conversion element 10C) with a perovskite compound to be described later as a light absorber.

In the invention, the light absorber may contain at least one type of perovskite compound, or may contain two or more types of perovskite compounds.

The photosensitive layer 13 may be a single layer or a lamination layer of two or more layers. When the photosensitive layer 13 has a lamination structure of two or more layers, layers formed of different light absorbers may be laminated, or an intermediate layer containing a hole transport material may be laminated between photosensitive layers.

The aspect in which the photosensitive layer 13 is on the conductive support 11 is as described above. The photosensitive layer 13 is preferably provided on the porous layer 12 or the blocking layer 14 such that excited electrons flow to the conductive support 11. At this time, the photosensitive layer 13 may be provided on a part or the whole of the surface of the porous layer 12 or the blocking layer 14.

The thickness of the photosensitive layer 13 is appropriately set according to the aspect in which the photosensitive layer 13 is on the conductive support 11, and is not particularly limited. For example, the thickness of the photosensitive layer 13 (when the porous layer 12 is provided, a total thickness including the thickness of the porous layer 12) is preferably 0.1 μm to 100 μm, more preferably 0.1 μm to 50 μm, and particularly preferably 0.3 μm to 30 μm. The thickness of the photosensitive layer 13 can be measured in the same manner as in the case of the thickness of the porous layer 12. When the photosensitive layer 13 has a thin film shape, a distance from an interface between the photosensitive layer 13 and the porous layer 12 to an interface between the photosensitive layer 13 and the hole transport layer 3 along a direction perpendicular to the surface of the porous layer 12 is set as the thickness of the photosensitive layer 13.

The photoelectric conversion element 10B shown in FIG. 2 has a photosensitive layer 13B having a larger thickness than the photosensitive layer 13A of the photoelectric conversion element 10A shown in FIG. 1. In this case, the perovskite compound as a light absorber may be a hole transport material as in the case of the above-described compound having a perovskite crystal structure as a material which forms the porous layer 12.

[Light Absorber]

The photosensitive layer 13 contains a perovskite compound having “a group I element of the periodic table or a cationic organic group A”, “a metal atom M other than the group I elements of the periodic table”, and “an anionic atom X”.

The group I element of the periodic table or the cationic organic group A, the metal atom M, and the anionic atom X of the perovskite compound exist as constituent ions of a cation (for convenience, may be referred to as cation A), a metal cation (for convenience, may be referred to as cation M), and an anion (for convenience, may be referred to as anion X), respectively, in the perovskite crystal structure.

In the invention, the cationic organic group is an organic group having such properties as to be a cation in the perovskite crystal structure, and the anionic atom is an atom having such properties as to be an anion in the perovskite crystal structure.

In the invention, the light absorber may contain at least one type of perovskite compound. In this case, one type of perovskite compound may be used singly, or two or more types of perovskite compounds may be used in combination.

This perovskite compound is not particularly limited as long as it is a compound which may have a perovskite crystal structure including the constituent ions.

In the perovskite compound used in the invention, the cation A is a cation of a group I element of the periodic table or an organic cation consisting of a cationic organic group A. The cation A is preferably an organic cation.

The cation of a group I element of the periodic table is not particularly limited, and preferred examples thereof include cations (Li⁺, Na⁺, K⁺, Cs+) of elements of lithium (Li), sodium (Na), potassium (K), and cesium (Cs). A cation (Cs⁺) of cesium is particularly preferred.

The organic cation is more preferably an organic cation of a cationic organic group represented by the following Formula (1).

R^{1a}—NH₃ Formula (1):

In the formula, R^{1a} indicates a substituent. R^{1a} is not particularly limited as long as it is an organic group. Preferred examples thereof include an alkyl group, a cycloalkyl group, an alkenyl group, an alkynyl group, an aryl group, a heteroaryl group, and a group which can be represented by the following Formula (2). Among these, an alkyl group and a group which can be represented by the following Formula (2) are more preferred.

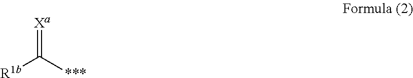

In the formula, X^{a} indicates NR^{1c}, an oxygen atom, or a sulfur atom. Each of R^{1b} and R^{1c} independently indicates a hydrogen atom or a substituent. *** indicates a bonding position with N of Formula (1).

In the invention, the organic cation of the cationic organic group A is preferably an organic ammonium cation consisting of an ammonium cationic organic group A produced by bonding R^{1a} and NH₃ in Formula (1). When this organic ammonium cation has a resonance structure, the organic cation includes a cation having a resonance structure in addition to the organic ammonium cation. For example, when X^{a} is NH (R^{1c} is a hydrogen atom) in the group which can be represented by Formula (2), the organic cation also includes, in addition to the organic ammonium cation of the ammonium cationic organic group produced by bonding the group which can be represented by Formula (2) and NH₃, an organic amidinium cation which is one of resonance structures of the organic ammonium cation. A cation represented by the following Formula (A^{am}) can be exemplified as the organic amidinium cation consisting of the amidinium cationic organic group. In this description, the cation represented by the following Formula (A^{am}) may be represented as “R^{1b}C(═NH)—NH₃” for convenience.

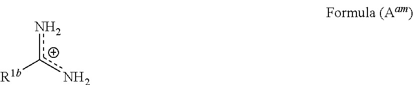

The alkyl group is preferably an alkyl group having 1 to 18 carbon atoms, and more preferably an alkyl group having 1 to 6 carbon atoms. Examples thereof include methyl, ethyl, propyl, isopropyl, butyl, tert-butyl, pentyl, and hexyl.

The cycloalkyl group is preferably a cycloalkyl group having 3 to 8 carbon atoms, and examples thereof include cyclopropyl, cyclopentyl, and cyclohexyl.

The alkenyl group is preferably an alkenyl group having 2 to 18 carbon atoms, and examples thereof include vinyl, allyl, butenyl, and hexenyl.

The alkynyl group is preferably an alkynyl group having 2 to 18 carbon atoms, and examples thereof include ethynyl, butynyl, and hexynyl.

The aryl group is preferably an aryl group having 6 to 14 carbon atoms, and examples thereof include phenyl.

The heteroaryl group includes a group formed only of an aromatic hetero ring and a group formed of a condensed hetero ring obtained by condensing an aromatic hetero ring with other rings such as an aromatic ring, an aliphatic ring, and a hetero ring.

A nitrogen atom, an oxygen atom, and a sulfur atom are preferred as a ring-constituent hetero atom constituting the aromatic hetero ring. The number of membered rings of the aromatic hetero ring is preferably 5 or 6.

Examples of the five-membered aromatic hetero ring and the condensed hetero ring including a five-membered aromatic hetero ring include ring groups of a pyrrole ring, an imidazole ring, a pyrazole ring, an oxazole ring, a thiazole ring, a triazole ring, a furan ring, a thiophene ring, a benzoimidazole ring, a benzoxazole ring, a benzothiazole ring, an indoline ring, and an indazole ring. Examples of the six-membered aromatic hetero ring and the condensed hetero ring including a six-membered aromatic hetero ring include ring groups of a pyridine ring, a pyrimidine ring, a pyrazine ring, a triazine ring, a quinoline ring, and a quinazoline ring.

In the group which can be represented by Formula (2), X^{a} indicates NR^{1c}, an oxygen atom, or a sulfur atom, and is preferably NR^{1c}. Here, R^{1c} is preferably a hydrogen atom, an alkyl group, a cycloalkyl group, an alkenyl group, an alkynyl group, an aryl group, or a heteroaryl group, and more preferably a hydrogen atom.

R^{1b} indicates a hydrogen atom or a substituent, and is preferably a hydrogen atom. Examples of the substituent which can be taken by R^{1b} include a hydrogen atom, an alkyl group, a cycloalkyl group, an alkenyl group, an alkynyl group, an aryl group, and a heteroaryl group.

The alkyl group, the cycloalkyl group, the alkenyl group, the alkynyl group, the aryl group, and the heteroaryl group, which can be taken by R^{1b} and R^{1c}, are synonymous with the groups of R^{1a}, and preferred groups are also the same as those of R^{1a}.

Examples of the group which can be represented by Formula (2) include formimidoyl (HC(═NH)—), acetoimidoyl (CH₃C(═NH)—), and propionimidoyl (CH₃CH₂C(═NH)—). Among these, formimidoyl is preferred.

Any of the alkyl group, the cycloalkyl group, the alkenyl group, the alkynyl group, the aryl group, the heteroaryl group, and the group which can be represented by Formula (2), all of which can be taken by R^{1a}, may have a substituent. The substituent that R^{1a} may have is not particularly limited, but examples thereof include an alkyl group, a cycloalkyl group, an alkenyl group, an alkynyl group, an aryl group, a heterocyclic group, an alkoxy group, an alkylthio group, an amino group, an alkylamino group, an arylamino group, an acyl group, an alkoxycarbonyl group, an aryloxycarbonyl group, an acylamino group, a sulfonamide group, a carbamoyl group, a sulfamoyl group, a halogen atom, a cyano group, a hydroxy group, and a carboxy group. Each substituent that R^{1a} may have may be further substituted with a sub stituent.

In the perovskite compound used in the invention, the metal cation M is not particularly limited as long as it is a cation of a metal atom M other than the group I elements of the periodic table, and is a cation of a metal atom which may have the perovskite crystal structure. Examples of such a metal atom include metal atoms of calcium (Ca), strontium (Sr), cadmium (Cd), copper (Cu), nickel (Ni), manganese (Mn), iron (Fe), cobalt (Co), palladium (Pd), germanium (Ge), tin (Sn), lead (Pb), ytterbium (Yb), europium (Eu), and indium (In). Among these, a Pb atom or a Sn atom is particularly preferred as the metal atom M. M may be one type of metal atoms or two or more types of metal atoms. When M is two or more types of metal atoms, two types of Pb and Sn are preferred. At this time, the ratio of the metal atoms is not particularly limited.

In the perovskite compound used in the invention, the anion X indicates an anion of the anionic atom X. The anion is preferably an anion of a halogen atom. Examples of the halogen atom include a fluorine atom, a chlorine atom, a bromine atom, and an iodine atom. The anion X may be anions of one type of anionic atoms or anions of two or more types of anionic atoms. When the anion X is anions of two or more types of anionic atoms, anions of two types of halogen atoms, particularly, an anion of a bromine atom and an anion of an iodine atom are preferred. At this time, the ratio of the anions of the anionic atoms is not particularly limited.

The perovskite compound used in the invention has a perovskite crystal structure having the above-described constituent ions, and a perovskite compound represented by the following Formula (I) is preferred.

AₐMₘXₓ Formula (I):

In the formula, A indicates a group I element of the periodic table or a cationic organic group. M indicates a metal atom other than the group I elements of the periodic table. X indicates an anionic atom.

a indicates 1 or 2, m indicates 1, and a, m, and x satisfy a+2m=x.

In Formula (I), the group I element of the periodic table or the cationic organic group A forms the cation A of the perovskite crystal structure. Accordingly, the group I element of the periodic table and the cationic organic group A are not particularly limited as long as the element or the group can form the cation A and can constitute the perovskite crystal structure. The group I element of the periodic table or the cationic organic group A is synonymous with the group I element of the periodic table or the cationic organic group in the description of the cation A, and preferred examples thereof are also the same as those of the group I element of the periodic table or the cationic organic group in the description of the cation A.

The metal atom M is a metal atom which forms the metal cation M of the perovskite crystal structure. Accordingly, the metal atom M is not particularly limited as long as it is an atom other than the group I elements of the periodic table, and is an atom which can form the metal cation M and can constitute the perovskite crystal structure. The metal atom M is synonymous with the metal atom in the description of the metal cation M, and preferred examples thereof are also the same as those of the metal atom in the description of the metal cation M.

The anionic atom X forms the anion X of the perovskite crystal structure. Accordingly, the anionic atom X is not particularly limited as long as it is an atom which can form the anion X and can constitute the perorvskite crystal structure. The anionic atom X is synonymous with the anionic atom in the description of the anion X, and preferred examples thereof are also the same as those of the anionic atom in the description of the anion X.

The perovskite compound represented by Formula (I) is a perovskite compound represented by the following Formula (I-1) when a is 1, and the perovskite compound represented by Formula (I) is a perovskite compound represented by the following Formula (I-2) when a is 2.

AMX₃ Formula (I-1):

A₂MX₄ Formula (I-2):

In Formulae (I-1) and (I-2), A indicates a group I element of the periodic table or a cationic organic group, and is synonymous with A of Formula (I). Preferred examples thereof are also the same as those of A.

M indicates a metal atom other than the group I elements of the periodic table, and is synonymous with M of Formula (I). Preferred examples thereof are also the same as those of M.

X indicates an anionic atom, and is synonymous with X of Formula (I). Preferred examples thereof are also the same as those of X.

Here, the perovskite crystal structure will be described.

As described above, the perovskite crystal structure contains the cation A, the metal cation M, and the anion X as constituent ions.

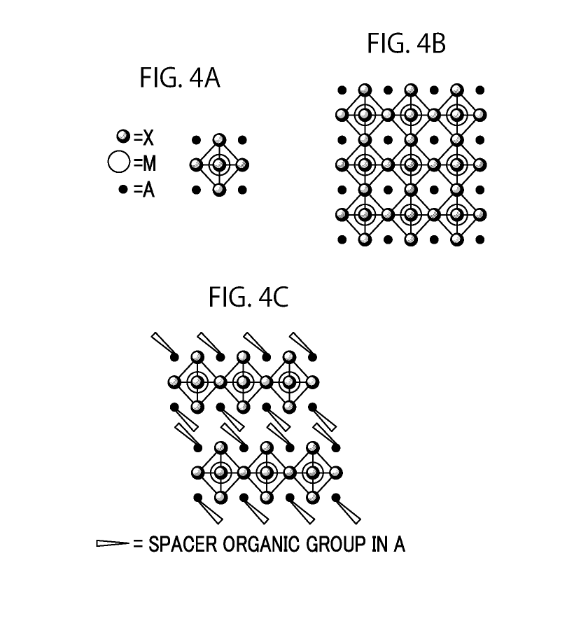

FIG. 4A is a diagram showing a fundamental unit lattice of the perovskite crystal structure, and FIG. 4B is a diagram showing a structure in which fundamental unit lattices are three-dimensionally continuous to each other in the perovskite crystal structure. FIG. 4C is a diagram showing a layered structure in which an inorganic layer and an organic layer are alternately laminated in the perovskite crystal structure.

The perovskite compound represented by Formula (I-1) has a cubic fundamental unit lattice in which, as shown in FIG. 4A, a cation A is disposed at each apex, a metal cation M is disposed at a body center, and an anion X is disposed at each face center of the cubic having the metal cation M as a center. In addition, the perovskite compound has a structure in which, as shown in FIG. 4B, one fundamental unit lattice shares a cation A and an anion X with each of other adjacent 26 fundamental unit lattices (surrounding the circumference) and fundamental unit lattices are three-dimensionally continuous to each other.

The perovskite compound represented by Formula (I-2) is the same as the perovskite compound represented by Formula (I-1) in terms of the fact that a MX₆ octahedron formed of a metal cation M and an anion X is provided, but is different therefrom in terms of the fundamental unit lattices and the arrangement form thereof. That is, the perovskite compound represented by Formula (I-2) has a layered structure in which, as shown in FIG. 4C, an inorganic layer formed by arranging MX₆ octahedrons two-dimensionally (in a plane shape) in a layer and an organic layer formed by inserting a cation A between inorganic layers are alternately laminated.

In such a layered structure, the fundamental unit lattices share cations A and anions X with other adjacent fundamental unit lattices in the surface of the same layer. The fundamental unit lattices do not share cations A and anions X in a different layer. This layered structure is a two-dimensional layered structure in which the inorganic layer is divided by the organic group of the cation A. As shown in FIG. 4C, the organic group in the cation A functions as a spacer organic group between the inorganic layers.

Regarding the perovskite compound having a layered structure, for example, New. J. Chem., 2008, 32, 1736 can be referred to.

The crystal structure of the perovskite compound is determined according to the cation A (group I element of the periodic table or cationic organic group A). For example, when the cation A is a cation of a group I element of the periodic table or an organic cation of a cationic organic group A having a substituent R^{1a} having one carbon atom and the like, the perovskite compound is represented by Formula (I-1) and is likely to have a cubic crystal structure. Examples of such a cation A include cations of CH₃—NH₃ and H—C(═NH)—NH₃ among organic cations having a group which can be represented by Formula (2).

When the cation A is a cation of a cationic organic group A having a substituent R^{1a} having two or more carbon atoms and the like, the perovskite compound is represented by Formula (I-2) and is likely to have a layered crystal structure. Examples of such a cation A include an organic cation of a cationic organic group A having an alkyl group, a cycloalkyl group, an alkenyl group, an alkynyl group, an aryl group, a heteroaryl group, or a group which can be represented by Formula (2) (when R^{1b} and R^{1c} are substituents), which have been described as the substituent R^{1a} and have two or more carbon atoms.

The perovskite compound used in the invention may be either a compound represented by Formula (I-1) or a compound represented by Formula (I-2), or may be a mixture thereof. Accordingly, in the invention, at least one type of perovskite compound may exist as the light absorber, and there is no need to strictly and clearly distinguish the compound according to the composition formula, molecular formula, crystal structure, and the like.

Hereinafter, specific examples of the perovskite compound used in the invention will be given, but the invention is not limited thereto. In the following description, the perovskite compound is classified into a compound represented by Formula (I-1) and a compound represented by Formula (I-2) in the description. However, even when a compound is exemplified as the compound represented by Formula (I-1), the exemplified compound may become the compound represented by Formula (I-2) or a mixture of the compound represented by Formula (I-1) and the compound represented by Formula (I-2) depending on synthesis conditions and the like. Similarly, even when a compound is exemplified as the compound represented by Formula (I-2), the exemplified compound may become the compound represented by Formula (I-1) or a mixture of the compound represented by Formula (I-1) and the compound represented by Formula (I-2).

Specific examples of the compound represented by Formula (I-1) include CH₃NH₃PbCl₃, CH₃NH₃PbBr₃, CH₃NH₃PbI₃, CH₃NH₃PbBrI₂, CH₃NH₃PbBr₂I, CH₃NH₃SnBr₃, CH₃NH₃SnI₃, and CH(═NH)NH₃PbI₃.

Specific examples of the compound represented by Formula (I-2) include (C₂H₅NH₃)₂PbI₄, (CH₂═CHNH₃)₂PbI₄, (CH═CNH₃)₂PbI₄, (n-C₃H₇NH₃)₂PbI₄, (n-C₄H₉NH₃)₂PbI₄, (C₆H₅NH₃)₂PbI₄, (C₆H₃F₂NH₃)₂PbI₄, (C₆F₅NH₃)₂PbI₄, and (C₄H₃SNH₃)₂PbI₄.

Here, C₄H₃SNH₃ in (C₄H₃SNH₃)₂PbI₄ is aminothiophene.

The perovskite compound can be synthesized from MX₂ and AX. For example, the above-described J. Am. Chem. Soc., 2009, 131 (17), 6050-6051 can be exemplified. Akihiro Kojima, Kenjiro Teshima, Yasuo Shirai, and Tsutomu Miyasaka, “Organometal Halide Perovskites as Visible-Light Sensitizers for Photovoltaic Cells” and J. Am. Chem. Soc., 2009, 131 (17), 6050-6051 can also be exemplified.

The light absorber may be used in such an amount as to cover at least a part of a light incident surface among the surfaces of the porous layer 12 or the blocking layer 14, and is preferably used in such an amount as to cover the entire light incident surface.

<Hole Transport Layer 3>

The hole transport layer 3 has a function to replenish electrons to an oxidant of the light absorber, and is preferably a solid-state layer. The hole transport layer 3 is preferably provided between the photosensitive layer 13 of the first electrode 1 and the second electrode 2.

In an embodiment of the invention, the hole transport layer 3 contains at least one type of hole transport material of which the energy level of the HOMO (energy level of the highest occupied molecular orbital) obtained by density functional theory (DFT) calculation is within a range of −4.50 eV to −5.00 eV. In this case, one type of hole transport material may be used singly, or two or more types of hole transport materials may be used in combination.

Here, the DFT calculation is performed using B3LYP as a functional and 3-21 G as a basis function with Gaussian 09.

In the invention, the energy level of the HOMO obtained by the DFT calculation is preferably within a range of −4.60 eV to −5.00 eV, and more preferably within a range of −4.60 eV to −4.80 eV.

The energy level of the HOMO corresponds to the energy of ionization.

Here, the energy of ionization can be obtained by ultraviolet photoelectron spectroscopy (UPS) or the like. Specifically, a single film of a hole transport material as a measurement target is formed on a glass substrate, and the measurement is performed on the single film using a measurement device such as ESCA 5600 UPS (ultraviolet photoemission spectroscopy) manufactured by ULVAC-PHI, Inc.

The hole transport material used in the invention may have any structure as long as the energy level of the HOMO obtained by the DFT calculation is within a range of −4.50 eV to −5.00 eV. For example, the hole transport material may be a polymer, an oligomer, or a monomer, that is, a compound that is not a polymer compound.

In the invention, it is preferable that the hole transport material is not a polymer compound. The molecular weight of the hole transport material that is not a polymer compound is, for example, preferably 400 to 10,000, more preferably 400 to 5,000, and even more preferably 400 to 3,000.

In terms of the chemical structure of the compound, the hole transport material is preferably an aryl or heteroarylamine compound, and preferably a compound in which all of bonds of nitrogen atoms are bonded to an aryl group or a heteroaryl group. Among these, a compound having 2 to 10 nitrogen atoms is preferred, a compound having 2 to 6 nitrogen atoms is more preferred, and a compound having 2 to 4 nitrogen atoms is even more preferred.

Here, examples of the aryl group include a phenyl group and a naphthyl group.

The heteroaryl group includes a group formed of an aromatic hetero ring. The number of membered rings of the aromatic hetero ring is preferably 5 or 6. A sulfur atom, a nitrogen atom, and an oxygen atom are preferred as a ring-constituent hetero atom of the aromatic hetero ring. The heteroaryl group also includes a group formed of a condensed hetero ring obtained by condensing the aromatic hetero ring with an aromatic hydrocarbon ring such as a benzene ring or a hetero ring.

Examples of the heteroaryl group include a thiophene ring, a furan ring, a pyrrole ring, a pyrazole ring, an imidazole ring, a triazole ring, an oxazole ring, a thiazole ring, a pyridine ring, a pyrazine ring, a pyrimidine ring, and a pyridazine ring.

The aryl group and the heteroaryl group may have a substituent T^{D1}. Examples of such a substituent T^{D1} include an alkyl group, an alkenyl group, an alkynyl group, a cycloalkyl group, an aryl group, a heterocyclic group, an alkoxy group, an aryloxy group, an alkylthio group, an arylthio group, a hydroxy group, an amino group, an alkylamino group, an arylamino group, a heterocyclic amino group, a halogen atom, an alkyl substituted silyl group, an acyl group, an alkoxycarbonyl group, an aryloxycarbonyl group, an amide group, a carbamoyl group, and a sulfamoyl group.

Among these, an alkyl group, an alkoxy group, an alkylthio group, an alkylamino group (preferably, dialkylamino group), an arylamino group (preferably, diarylamino group and N-alkyl-N-arylamino group), an alkyl substituted silyl group (also referred to as alkylsilyl group), an alkoxycarbonyl group, and an acyl group are preferred, and an alkyl group, an alkoxy group, an alkylthio group, a dialkylamino group, a diarylamino group, an N-alkyl-N-arylamino group, and an alkyl substituted silyl group are more preferred.

The substituent that the aryl group and the heteroaryl group may have is preferably a group having at least an alkyl moiety, and the number of carbon atoms of this alkyl moiety is preferably two or more. The number of carbon atoms of this alkyl moiety is more preferably 2 to 30, even more preferably 2 to 20, and particularly preferably 2 to 12.

The compound that is preferred as the hole transport material is a compound represented by the following Formula (D).

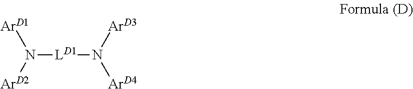

In Formula (D), L^{D1} indicates “an arylene group”, “a heteroarylene group”, or “a linking group in which at least two of arylene groups and heteroarylene groups are combined”. Each of Ar^{D1} Ar^{D4} independently indicates an aryl group or a heteroaryl group. Ar^{D1} to Ar^{D4} may have a substituent. Ar^{D1} and Ar^{D2}, and Ar^{D3} and Ar^{D4} may be respectively bonded to form a ring.

Examples of the “arylene group” of L^{D1} include a phenylene group and a naphthylene group, and a phenylene group is preferred. In addition, as the “heteroarylene group” of L^{D1}, a divalent group of an aromatic hetero ring exemplified as a heteroaryl group of the heteroarylamine compound is preferred, and the preferred range thereof is also the same.

The “linking group in which at least two of arylene groups and heteroarylene groups are combined” of L^{D1} may be a linking group in which the same type of groups are combined, or a linking group in which different types of groups are combined. Examples of L^{D1} include a group in which a plurality of arylene groups are linked, a group in which a plurality of heteroarylene groups are linked, and a group in which an arylene group and a heteroarylene group are linked alternately, and randomly or in a block-forming manner.

The arylene group and the heteroarylene group may have a substituent. As such a substituent, the substituent T^{D1} that the aryl group and the heteroaryl group may have can be exemplified.

Here, when the linking group is a group in which a plurality of arylene groups or heteroarylene groups are linked, the neighboring rings may be linked to form a ring. Such a ring is preferably a five-membered ring or a six-membered ring, or may be a spiro ring. The formed ring may be a carbon ring formed only of carbon atoms, or a hetero ring including silyl atoms. An aromatic hydrocarbon ring such as a benzene ring or a hetero ring may be condensed with the formed ring.

L^{D1} is preferably a group represented by any one of the following Formulae (L-1) to (L-4).

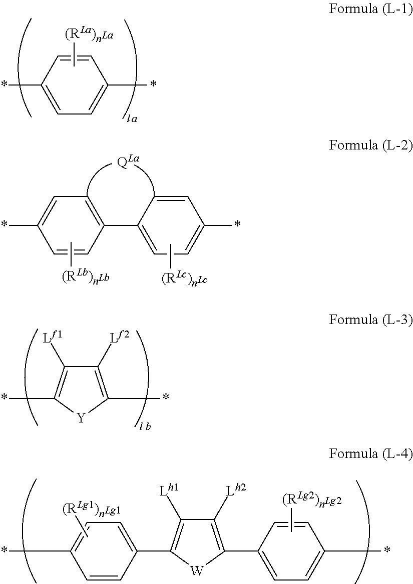

In the formulae, each of R^{La} to R^{Lc} independently indicates a substituent. n^{La} indicates an integer of 0 to 4, and each of n^{Lb} and n^{Lc} independently indicates an integer of 0 to 3. la indicates an integer of 1 to 4. Q^{La} indicates a group which forms a hydrocarbon ring or a spiro ring of a five-membered ring, a group which forms a hydrocarbon ring or a spiro ring of a six-membered ring, or —Si(Rx)(Ry)-. Here, each of Rx and Ry independently indicates an alkyl group.

Each of Y and Z independently indicates O, S, or —CH═N—. Y is preferably —CH═N—, and Z is preferably S. Each of R^{Lg1} and R^{Lg2} independently indicates a sub stituent. Each of R^{Lf1}, R^{Lf2}, R^{Lh1}, and R^{Lh2} independently indicates a hydrogen atom or a substituent. Each of n^{Lg1} and n^{Lg2} independently indicates an integer of 0 to 4. lb indicates an integer of 1 to 4.

* indicates a bonding position with N of Formula (D).

Examples of the substituents of R^{La} to R^{Lc}, R^{Lg1}, and R^{Lg2} include the substituent T^{D1} that the aryl group and the heteroaryl group may have, and the preferred ranges thereof are also the same.

Each of R^{Lf1}, R^{Lf2}, R^{Lh1}, and R^{Lh2} is preferably a hydrogen atom.

When R^{Lf1}, R^{Lf2}, R^{Lh1}, and R^{Lh2} are substituents, examples of the substituents include the substituent T^{D1} that the aryl group and the heteroaryl group may have, and the preferred ranges thereof are also the same. In the invention, R^{Lf1} and R^{Lf2} (hereinafter, referred to as R^{Lf}), and R^{Lh1} and R^{Lh2} (hereinafter, referred to as R^{Lh}) include an aspect in which these are not respectively bonded to each other and an aspect in which these are respectively bonded to each other to form a ring. Each of the ring formed by R^{Lf} and the ring formed by R^{Lh} is preferably a five-membered ring or a six-membered ring, and may be an aromatic ring or a hetero ring. For example, when R^{Lf} or R^{Lh} is an alkenyl group, R^{Lf} or R^{Lh} is bonded to each other and can form a ring including Y of Formula (L-3) or Z of Formula (L-4) and a benzene ring. When R^{Lf} or R^{Lh} is an alkoxy group, R^{Lf} or R^{Lh} is bonded to each other and can form a ring including Y of Formula (L-3) or Z of Formula (L-4) and a 1,4-dioxane ring.

All of n^{La}, n^{Lb}, n^{Lc}, n^{Lg1} and n^{Lg2} are preferably 0 or 1, and more preferably 0.

la is preferably 2 or 3. lb is preferably 2 or 3, and more preferably 2.

Each of Rx and Ry is preferably an alkyl group having 1 to 18 carbon atoms, and more preferably an alkyl group having 2 to 10 carbon atoms. Examples thereof include methyl, ethyl, hexyl, and octyl.

Formula (L-2) including Q^{La} is preferably a group represented by any one of the following Formulae (L-2a) to (L-2f), more preferably a group represented by any one of Formulae (L-2a), (L-2c), and (L-2d), and more preferably a group represented by Formula (L-2a) or (L-2c).

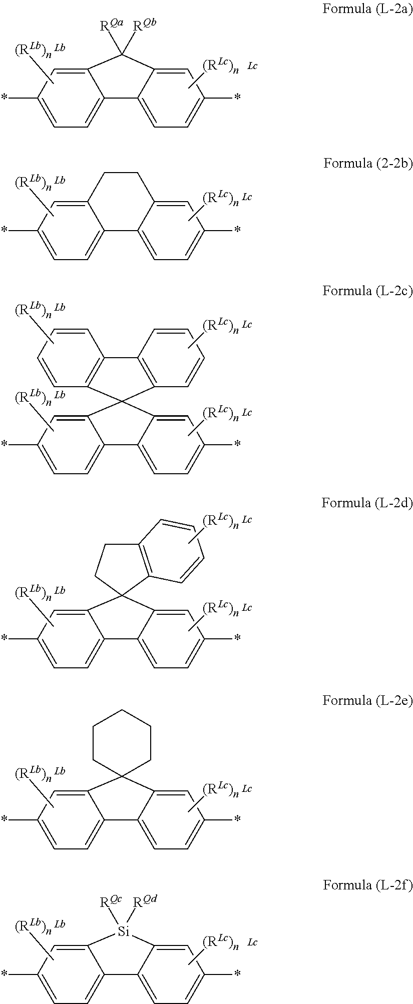

In the formulae, * indicates a bonding position with N of Formula (D).

R^{Lb}, R^{Lc}, n^{Lb}, and n^{Lc} are synonymous with R^{Lb}, R^{Lc}, n^{Lb}, and n^{Lc} of Formula (L-2), and the preferred ranges thereof are also the same. R^{Qa}, R^{Qb}, R^{Qc}, and R^{Qd} are synonymous with Rx and Ry of Formula (L-2), and the preferred ranges thereof are also the same. Each of R^{Qa} and R^{Qb} is more preferably methyl, ethyl, or isopropyl, and each of R^{Qc} and R^{Qd} is more preferably ethyl or n-hexyl.

The aryl group and the heteroaryl group of Ar^{D1} to Ar^{D4} are synonymous with the aryl group and the heteroaryl group of the heteroarylamine compound, and the preferred ranges thereof are also the same.

In the invention, at least one of the aryl group and the heteroaryl group of Ar^{D1} to Ar^{D4} preferably has the following substituent T^{D2}.

Examples of the preferred substituent T^{D2} of at least one of the aryl group and the heteroaryl group include groups of the following 1) and groups of the following 2).

1) As a group T^{D2-1}, an alkyl group, an alkoxy group, an alkylthio group, an alkylamino group, a dialkylamino group, an alkoxycarbonyl group, an alkylsilyl group, or an acyl group, which has two or more carbon atoms, can be exemplified.

2) As a group T^{D2-2}, an aryl group or a heteroaryl group substituted with the group T^{D2-1} of 1) can be exemplified.

As the group T^{D2-1} of 1), the above-described group having 3 or more carbon atoms and the above-described group having 4 or more carbon atoms can also be exemplified.

Among the groups of T^{D2}, an alkyl group having two or more carbon atoms, an alkoxy group having two or more carbon atoms, an aryl group substituted with an alkyl group having two or more carbon atoms, an aryl group substituted with an alkoxy group having two or more carbon atoms, a heteroaryl group substituted with an alkyl group having two or more carbon atoms, or a heteroaryl group substituted with an alkoxy group having two or more carbon atoms can be exemplified as a more preferred substituent.

Among these, a group represented by any one of the following Formulae (R-1) to (R-3) is preferred, and a group represented by Formula (R-2) or (R-3) is more preferred as Ar^{D1}.

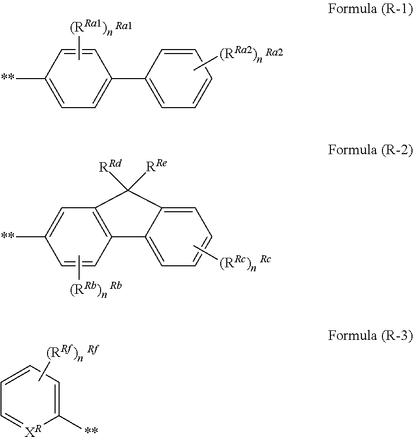

In the formulae, X^{R} indicates CH or N. Each of R^{Ra1}, R^{Ra2}, R^{Rb}, R^{Rc}, and R^{Rf} independently indicates a substituent. n^{Ra1}, n^{Rc}, and n^{Rf} indicate an integer of 0 to 4, n^{Ra2} indicates an integer of 0 to 5, and n^{Rb} indicates an integer of 0 to 3. Each of R^{Rd} and R^{Re} independently indicates an alkyl group, and R^{Rd} and R^{Re} may be bonded to each other to form a ring. ** indicates a bonding position with N of any one of Formulae (D) and (D-1) to (D-4).

R^{Ra1} and n^{Ra1} are synonymous with R^{La1} and n^{La1} of Formula (D-1) to be described later, and R^{Rb} to R^{Re} and n^{Rb} are synonymous with R^{Lb} to R^{Le} and n^{Lb} of Formula (D-2) to be described later. Examples of the substituents of R^{Ra2} and R^{Rc} include the substituent that the aryl group and the heteroaryl group may have.

In the invention, each of R^{Ra1}, R^{Ra2}, R^{Rb}, R^{Rc}, and R^{Rf} is more preferably the substituent T^{D2}.

Ar^{D2} to Ar^{D4} each may be a group represented by any one of Formulae (R-1) to (R-3).

The compound represented by Formula (D), that is, the hole transport material is more preferably a compound represented by any one of the following Formulae (D-1) to (D-4), and particularly preferably a compound represented by Formula (D-2) from the viewpoint of stability of the cell performance.

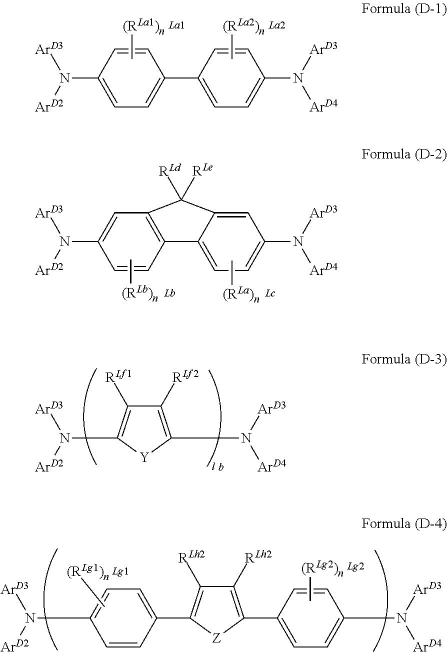

In Formulae (D-1) to (D-4), Ar^{D1} to Ar^{D4} are synonymous with Ar^{D1} to Ar^{D4} of Formula (D). Each of R^{La1}, R^{La2}, R^{Lb}, and R^{Lc} independently indicates a substituent. Each of n^{La1} and n^{La2} independently indicates an integer of 0 to 4, and each of n^{Lb} and n^{Lc} independently indicates an integer of 0 to 3. Each of R^{Ld} and R^{Le} independently indicates an alkyl group, and R^{Ld} and R^{Le} may be bonded to each other to form a ring.

Each of Y and Z independently indicates O, S, or —CH═N—. Y is preferably —CH═N—, and Z is preferably S. Each of R^{Lg1} and R^{Lg2} independently indicates a substituent. Each of R^{Lf1}, R^{Lf2}, R^{Lh1}, and R^{Lh2} independently indicates a hydrogen atom or a substituent. Each of n^{Lg1} and n^{Lg2} independently indicates an integer of 0 to 4. lb indicates an integer of 1 to 4.

R^{La1} and n^{L1a} are synonymous with R^{La} and n^{La} of Formula (L-1), and the preferred ranges thereof are also the same. R^{La2} and n^{L2a} are synonymous with the corresponding R^{La1} and n^{L1a}, and the preferred ranges thereof are also the same. R^{Lb}, R^{Lc}, n^{Lb}, and n^{Lc} are synonymous with R^{Lb}, R^{Lc}, n^{Lb}, and n^{Lc} of Formula (L-2). R^{Ld} and R^{Le} are synonymous with Rx and Ry of Formula (L-2), and the preferred ranges thereof are also the same.

Y is synonymous with Y of Formula (L-3), and the preferred range thereof is also the same. Z is synonymous with Z of Formula (L-4), and the preferred range thereof is also the same. R^{Lf1} and R^{Lf2} are synonymous with R^{Lf1} and R^{Lf2} of Formula (L-3), and the preferred ranges thereof are also the same. R^{Lg1}, R^{Lg2}, R^{Lh1}, and R^{Lh2} are synonymous with R^{Lg1}, R^{Lg2}, R^{Lh1}, and R^{Lh2} of Formula (L-4), and the preferred ranges thereof are also the same. n^{Lg1} and n^{Lg2} are synonymous with n^{Lg1} and n^{Lg2} of Formula (L-4), and the preferred ranges thereof are also the same.

Hereinafter, specific examples of the compound represented by Formula (D) will be given, but the invention is not limited thereto.

Here, Me indicates methyl, Et indicates ethyl, and n-Pr indicates n-propyl.

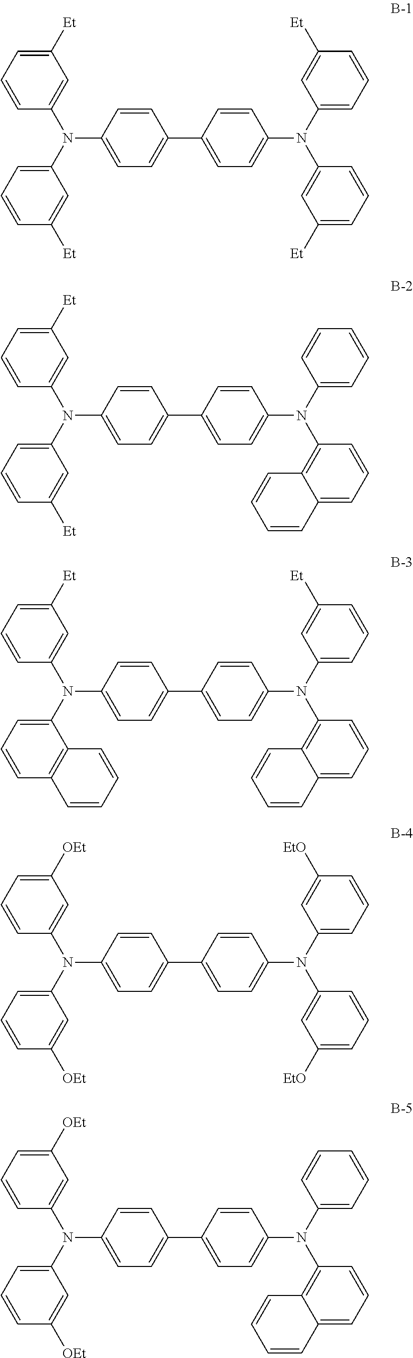

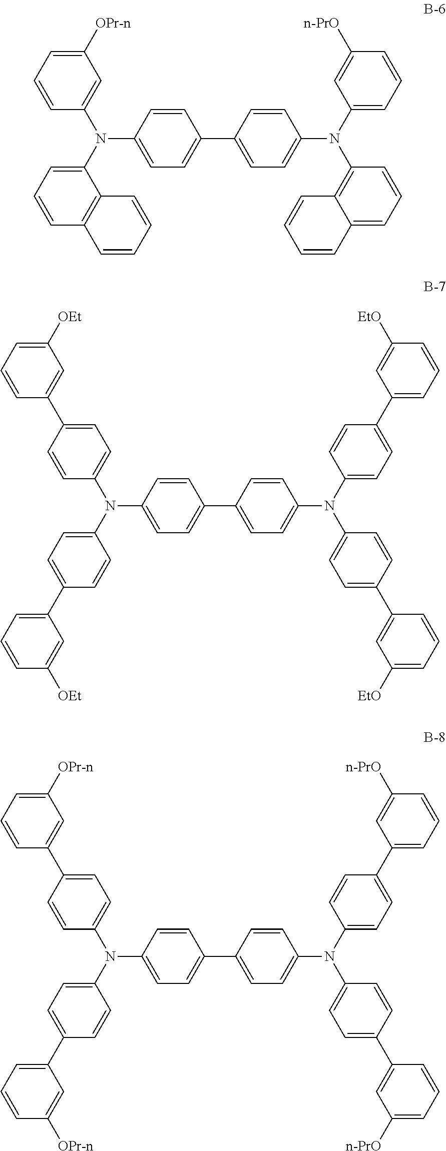

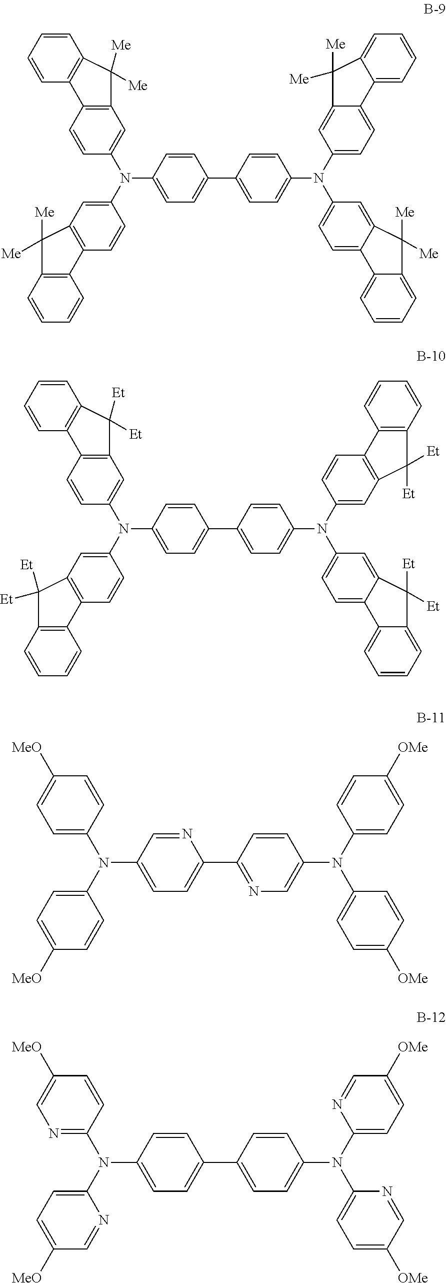 [SMILES: CC1(C)c2ccccc2-c2ccc(N(c3ccc(-c4ccc(N(c5ccc6c(c5)C(C)(C)c5ccccc5-6)c5ccc6c(c5)C(C)(C)c5ccccc5-6)cc4)cc3)c3ccc4c(c3)C(C)(C)c3ccccc3-4)cc21 ; CCC1(CC)c2ccccc2-c2ccc(N(c3ccc(-c4ccc(N(c5ccc6c(c5)C(CC)(CC)c5ccccc5-6)c5ccc6c(c5)C(CC)(CC)c5ccccc5-6)cc4)cc3)c3ccc4c(c3)C(CC)(CC)c3ccccc3-4)cc21 ; COc1ccc(N(c2ccc(OC)cc2)c2ccc(-c3ccc(N(c4ccc(OC)cc4)c4ccc(OC)cc4)cn3)nc2)cc1 ; COc1ccc(N(c2ccc(-c3ccc(N(c4ccc(OC)cn4)c4ccc(OC)cn4)cc3)cc2)c2ccc(OC)cn2)nc1]

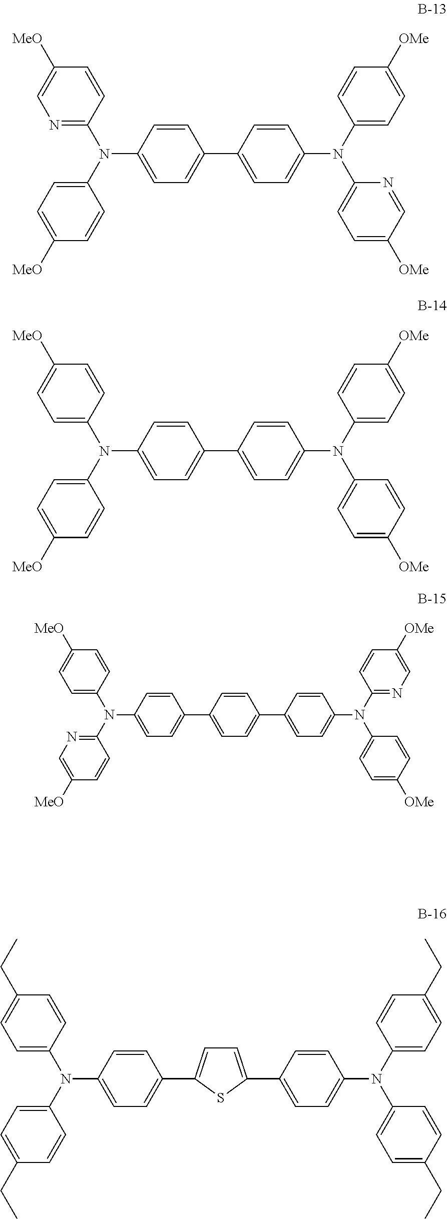 [SMILES: COc1ccc(N(c2ccc(-c3ccc(N(c4ccc(OC)cc4)c4ccc(OC)cn4)cc3)cc2)c2ccc(OC)cn2)cc1 ; COc1ccc(N(c2ccc(OC)cc2)c2ccc(-c3ccc(N(c4ccc(OC)cc4)c4ccc(OC)cc4)cc3)cc2)cc1 ; COc1ccc(N(c2ccc(-c3ccc(-c4ccc(N(c5ccc(OC)cc5)c5ccc(OC)cn5)cc4)cc3)cc2)c2ccc(OC)cn2)cc1 ; CCc1ccc(N(c2ccc(CC)cc2)c2ccc(-c3ccc(-c4ccc(N(c5ccc(CC)cc5)c5ccc(CC)cc5)cc4)s3)cc2)cc1]

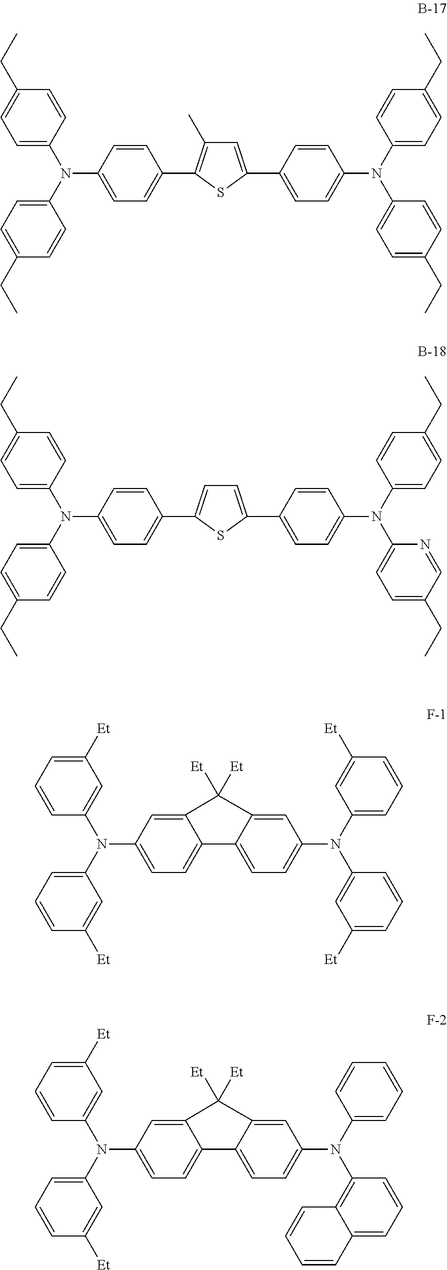 [SMILES: CCc1ccc(N(c2ccc(CC)cc2)c2ccc(-c3cc(C)c(-c4ccc(N(c5ccc(CC)cc5)c5ccc(CC)cc5)cc4)s3)cc2)cc1 ; CCc1ccc(N(c2ccc(CC)cc2)c2ccc(-c3ccc(-c4ccc(N(c5ccc(CC)cc5)c5ccc(CC)cn5)cc4)s3)cc2)cc1 ; CCc1cccc(N(c2cccc(CC)c2)c2ccc3c(c2)C(CC)(CC)c2cc(N(c4cccc(CC)c4)c4cccc(CC)c4)ccc2-3)c1 ; CCc1cccc(N(c2cccc(CC)c2)c2ccc3c(c2)C(CC)(CC)c2cc(N(c4ccccc4)c4cccc5ccccc45)ccc2-3)c1]

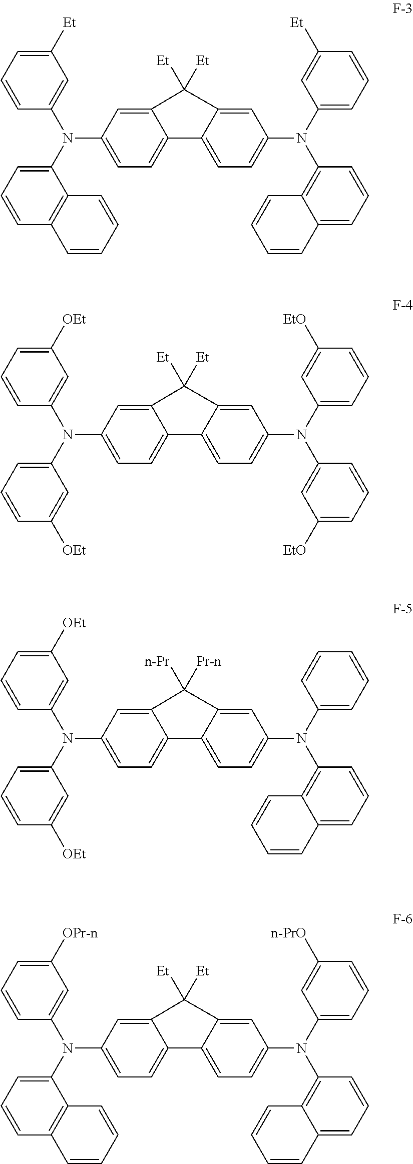

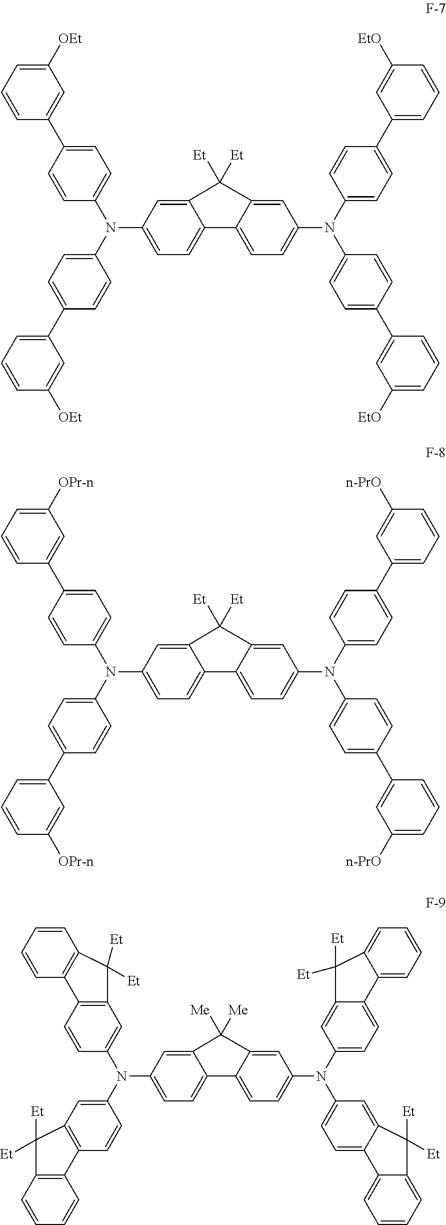

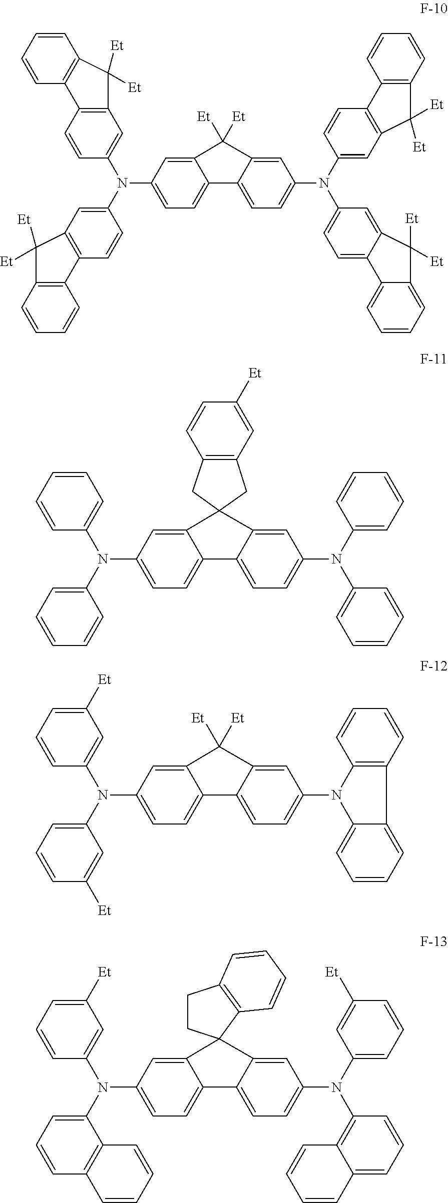

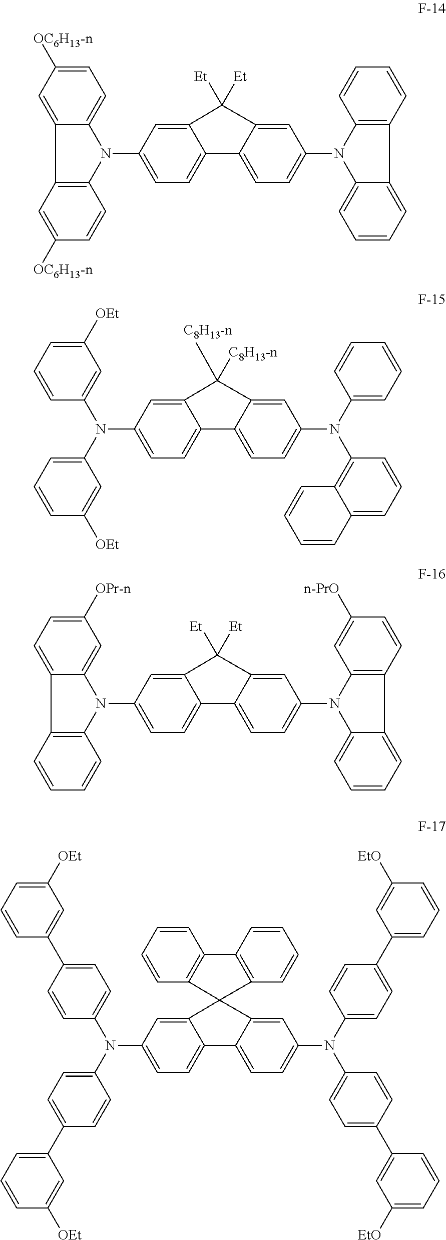

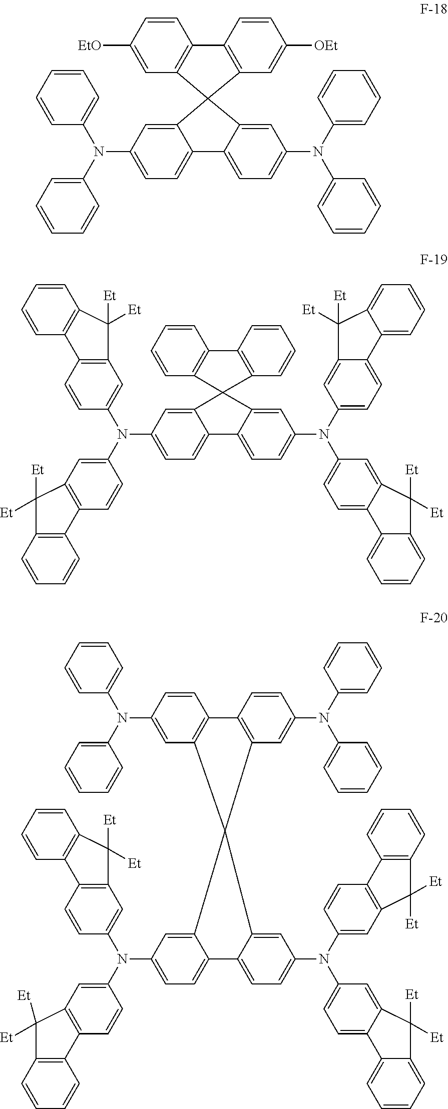 [SMILES: CCOc1ccc2c(c1)C1(c3cc(OCC)ccc3-2)c2cc(N(c3ccccc3)c3ccccc3)ccc2-c2ccc(N(c3ccccc3)c3ccccc3)cc21 ; CCC1(CC)c2ccccc2-c2ccc(N(c3ccc4c(c3)C(CC)(CC)c3ccccc3-4)c3ccc4c(c3)C3(c5ccccc5-c5ccccc53)c3cc(N(c5ccc6c(c5)C(CC)(CC)c5ccccc5-6)c5ccc6c(c5)C(CC)(CC)c5ccccc5-6)ccc3-4)cc21 ; CCC1(CC)c2ccccc2-c2ccc(N(c3ccc4c(c3)C(CC)(CC)c3ccccc3-4)c3ccc4c(c3)C3(c5cc(N(c6ccccc6)c6ccccc6)ccc5-c5ccc(N(c6ccccc6)c6ccccc6)cc53)c3cc(N(c5ccc6c(c5)C(CC)(CC)c5ccccc5-6)c5ccc6c(c5)C(CC)(CC)c5ccccc5-6)ccc3-4)cc21]

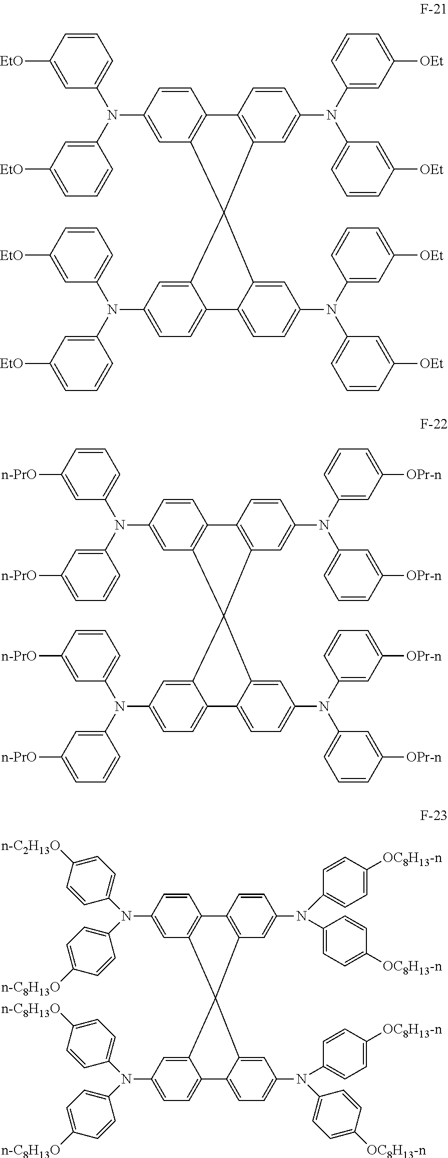

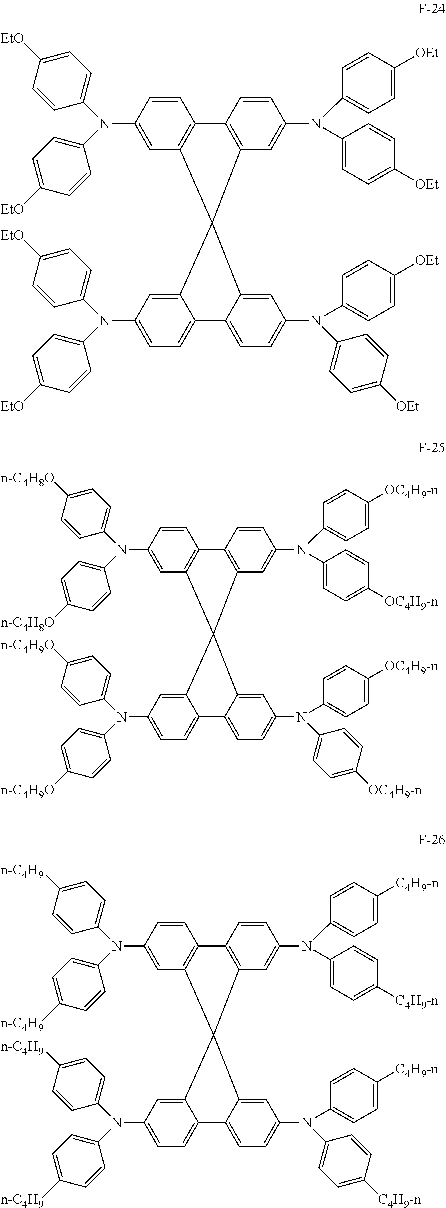

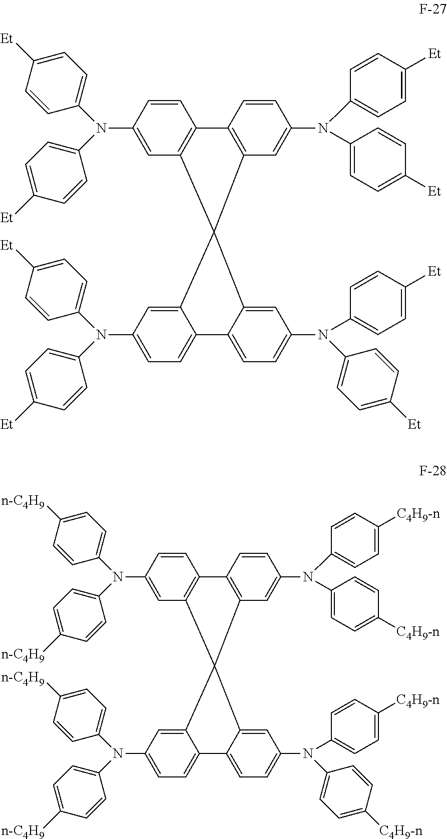

Examples of the compound represented by Formula (D) include, in addition to the above examples, 4,4′-bis[N-(1-naphthyl)-N-phenylamino]biphenyl (abbreviated as NPD) having two condensed aromatic rings described in U.S. Pat. No. 5,061,569A in the molecule, and 4,4′,4″-tris[N-(3-methylphenyl)-N-phenylamino]triphenylamine (abbreviated as MTDATA) in which three triphenylamine units are connected in a starburst form, described in JP1992-308688A (JP-H4-308688A).

The compound represented by Formula (D) can be synthesized according to the methods described in Comprehensive Organic Synthesis—Selectivity, Strategy, and efficiency in Modern Organic Chemistry.

In the invention, examples of the hole transport material which can be used in combination with the hole transport material of which the energy level of the HOMO is within a range of −4.50 eV to −5.00 eV include inorganic materials such as CuI and CuNCS and organic hole transport materials described in paragraphs 0209 to 0212 of JP2001-291534A. Examples of the organic hole transport materials include polythiophene (for example, poly(3-hexylthiophene-2,5-diyl) and polyethylenedioxythiophene (PEDOT)), conductive polymers such as polyaniline, polypyrrole, and polysilane of which the energy level of the HOMO is out of the range of −4.50 eV to −5.00 eV, a Spiro compound in which two rings share a central atom such as C and Si having a tetrahedral structure (for example, 2,2′,7,7′-tetrakis-(N,N-di-p-methoxyphenylamine)-9,9-spirobifluorene (Spiro-OMeTAD)), an aromatic amine compound such as triarylamine (for example, poly(triphenylamine), 4-(diethylamino)benzaldehyde diphenylhydrazone), a triphenylene compound, a nitrogen-containing heterocyclic compound, and a liquid crystalline cyano compound.

The hole transport material preferably includes only a hole transport material (compound) of which the energy level of the HOMO is within a range of −4.50 eV to −5.00 eV. When a hole transport material of which the energy level of the HOMO is out of the range of −4.50 eV to −5.00 eV is used in combination as the hole transport material, the hole transport material used in combination is preferably 95 parts by mass or less, and more preferably 90 parts by mass or less when all of the used hole transport materials are 100 parts by mass.

In the invention, the hole transport material is preferably a solid-state hole transport material which can be applied in a solution state and has excellent solubility.

The thickness of the hole transport layer 3 is not particularly limited, but is preferably 50 μm or less, more preferably 1 nm to 10 μm, even more preferably 5 nm to 5 μm, and particularly preferably 10 nm to 1 μm. The thickness of the hole transport layer 3 corresponds to a distance from the second electrode 2. This thickness can be measured by observing a cross-section of the photoelectric conversion element 10 using a scanning electron microscope (SEM) or the like.

In the invention, the total thickness of the photosensitive layer 13 and the hole transport layer 3 (when the porous layer 12 is provided, a total thickness of the porous layer 12, the photosensitive layer 13, and the hole transport layer 3) is not particularly limited. The total thickness is, for example, preferably 0.1 μm to 200 μm, more preferably 0.5 μm to 50 μm, and even more preferably 0.5 μm to 5 μm.

<Second Electrode 2>

The second layer 2 functions as a cathode in a solar cell. The second electrode 2 is not particularly limited as long as it has conductive properties, and generally may have the same configuration as the conductive support 11. The support 11a is not essentially required when a sufficient strength is kept.

As the structure of the second electrode 2, a structure having a high current collection effect is preferred. In order to allow light to reach the photosensitive layer 13, at least one of the conductive support 11 and the second electrode 2 should be substantially transparent. In the solar cell of the invention, it is preferable that the conductive support 11 is transparent and solar light is made incident from the side of the support 11a. In this case, it is more preferable that the second electrode 2 has light reflection properties.

Examples of the material which forms the second electrode 2 include metals such as platinum (Pt), gold (Au), nickel (Ni), copper (Cu), silver (Ag), indium (In), ruthenium (Ru), palladium (Pd), rhodium (Rh), iridium (Ir), and osmium (Os), the above-described conductive metal oxides, and carbon materials. The carbon materials may be conductive materials formed by bonding carbon atoms to each other, and examples thereof include fullerene, carbon nano-tube, graphite, and graphene.

The second electrode 2 is preferably glass or plastic having a thin film (including thin film formed by deposition) of a metal or a conductive metal oxide, and particularly preferably glass having a Au or Pt thin film or glass on which Pt is deposited.

The thickness of the second electrode 2 is not particularly limited, and is preferably 0.01 μm to 100 μm, more preferably 0.01 μm to 10 μm, and particularly preferably 0.01 μm to 1 μm.

<Other Configurations>

In the invention, in order to prevent the contact between the first electrode 1 and the second electrode 2, a spacer or a separator can also be used in place of or together with the blocking layer 14.

In addition, a hole blocking layer may be provided between the second electrode 2 and the hole transport layer 3.

<<Solar Cell>>

For example, as shown in FIGS. 1 to 3, the solar cell of the invention is configured such that the photoelectric conversion element 10 is allowed to work with respect to the external circuit 6. As the external circuit connected to the first electrode 1 (conductive support 11) and the second electrode 2, a known external circuit can be used with no particular limits.

Side surfaces of the solar cell of the invention are preferably sealed with a polymer, an adhesive, or the like in order to prevent deterioration and transpiration of the constituent materials.

The solar cell having the photoelectric conversion element of the invention applied thereto is not particularly limited, and examples thereof include solar cells described in KR10-1172374B, J. Am. Chem. Soc., 2009, 131 (17), 6050-6051, Science, 338, 643 (2012), and Nature Photonics Published Online, 5, May, 2013.

<<Method of Manufacturing Photoelectric Conversion Element and Solar Cell>>

The photoelectric conversion element and the solar cell according to an embodiment of the invention can be manufactured according to known manufacturing methods such as methods described in J. Am. Chem. Soc., 2009, 131 (17), 6050-6051, Science, 338, 643 (2012), and Nature Photonics Published Online, 5, May, 2013.

Hereinafter, a method of manufacturing the photoelectric conversion element and the solar cell according to an embodiment of the invention will be simply described.

At least one of the blocking layer 14 and the porous layer 12 is formed on a surface of the conductive support 11, if desired.

The blocking layer 14 can be formed through, for example, a method including: applying a dispersion containing the above-described insulating substance or its precursor compound to the surface of the conductive support 11; and performing baking, a spray pyrolysis method, or the like.

The material which forms the porous layer 12 is preferably used as fine particles, and more preferably as a dispersion containing fine particles.

The method of forming the porous layer 12 is not particularly limited, but examples thereof include a wet method, a dry method, and other methods (for example, method described in Chemical Review, vol. 110, p. 6595 (2010)). In these methods, baking is preferably performed for 10 minutes to 10 hours at a temperature of 100° C. to 800° C. after application of a dispersion (paste) to the surface of the conductive support 11 or the surface of the blocking layer 14. Accordingly, fine particles can be firmly adhered to each other.

When the baking is performed more than once, the temperature for baking other than final baking (temperature for baking other than final baking) may be lower than the temperature for final baking (final baking temperature). For example, when a titanium oxide paste is used, the temperature for baking other than final baking can be set within a range of 50° C. to 300° C. In addition, the final baking temperature can be set to be higher than the temperature for baking other than final baking within a range of 100° C. to 600° C. When a glass support is used as the support 11a, the baking temperature is preferably 60° C. to 500° C.

The amount of the porous material applied when forming the porous layer 12 is appropriately set according to the thickness of the porous layer 12 to be formed, the number of times of application, and the like, and is not particularly limited. The amount of the porous material applied per surface area of 1 m² of the conductive support 11 is, for example, preferably 0.5 g to 500 g, and more preferably 5 g to 100 g.

Next, the photosensitive layer 13 is provided.

First, a light absorber solution for forming the photosensitive layer 13 is prepared. The light absorber solution contains MX₂ and AX which are materials of the perovskite compound. Here, A, M, and X are synonymous with A, M, and X of Formula (I). In this light absorber solution, a molar ratio between MX₂ and AX is adjusted according to a of the perovskite compound (P) and the like.

Next, the prepared light absorber solution is applied to the surface of the porous layer 12 or the surface of the blocking layer 14 and is dried. Accordingly, the perovskite compound is formed on the surface of the porous layer 12 or the surface of the blocking layer 14.

On the photosensitive layer 13 provided in this manner, a hole transport material solution containing a hole transport material is applied and dried to form the hole transport layer 3.

In the hole transport material solution, the concentration of the hole transport material is preferably 0.1 M (mol/L) to 1.0 M (mol/L) from the viewpoint of excellent coatability and easy intrusion up to the inside of the holes of the porous layer 12 when the porous layer 12 is provided.

After the formation of the hole transport layer 3, the second electrode 2 is formed to manufacture a photoelectric conversion element and a solar cell.

The thickness of each layer can be adjusted by appropriately changing the concentration and the number of times of application of each dispersion liquid or solution. For example, when the thick photosensitive layer 13B shown in FIG. 2 or 3 is provided, the dispersion liquid may be applied and dried a plurality of times.

The above-described respective dispersion liquids and solutions may contain additives such as a dispersion auxiliary agent and a surfactant if necessary.

Examples of the solvent or dispersion medium used in the method of manufacturing the photoelectric conversion element and the solar cell include solvents described in JP2001-291534A, but the solvent or dispersion medium is not particularly limited thereto. In the invention, an organic solvent is preferred, and an alcohol solvent, an amide solvent, a nitrile solvent, a hydrocarbon solvent, a lactone solvent, and a mixed solvent of two or more thereof are more preferred. The mixed solvent is preferably a mixed solvent of solvents selected from an alcohol solvent, an amide solvent, a nitrile solvent, and a hydrocarbon solvent. Specifically, methanol, ethanol, γ-butyrolactone, chlorobenzene, acetonitrile, dimethylformamide (DMF), dimethylacetamide, or a mixed solvent thereof is preferred.

The method of applying the solution or dispersing agent which forms each layer is not particularly limited, and known methods such as spin coating, extrusion die coating, blade coating, bar coating, screen printing, stencil printing, roll coating, curtain coating, spray coating, dip coating, ink jet printing, and dipping can be used. Among these, spin coating, screen printing, dipping, and the like are preferred.

The solar cell is manufactured by connecting an external circuit to the first electrode 1 and the second electrode 2 of the photoelectric conversion element produced as described above.

### EXAMPLES

Hereinafter, the invention will be described in more detail based on the following examples, but is not limited thereto.

### Example 1

The photoelectric conversion element 10A and the solar cell shown in FIG. 1 were manufactured according to the following procedures. When the photosensitive layer 13 has a large thickness, the large thickness is provided to correspond to the photoelectric conversion element 10B and the solar cell shown in FIG. 2.

<Preparation of Solution for Blocking Layer>

A 15 mass % isopropanol solution of titanium diisopropoxide bis(acetylacetonato) (manufactured by Sigma-Aldrich Co. LLC.) was diluted with 1-butanol to prepare a 0.02 M solution for a blocking layer.

<Formation of Blocking Layer 14>

A fluorine-doped, conductive SnO₂ film (transparent electrode 11b) was formed on a glass substrate (support 11a, thickness: 2.2 mm) to produce a conductive support 11. Using the prepared 0.02 M solution for a blocking layer, a blocking layer 14 (thickness: 100 nm) was formed on the conductive SnO₂ film at 450° C. through a spray pyrolysis method.

<Preparation of Titanium Oxide Paste>

A titanium oxide paste was prepared by adding ethyl cellulose, lauric acid, and terpineol to an ethanol dispersion liquid of titanium oxide (anatase, average particle diameter: 20 nm).

<Formation of Porous Layer 12>

The prepared titanium oxide paste was applied to the blocking layer 14 through a screen printing method and was baked. Each of the application of the titanium oxide paste and the baking were performed two times. The first baking was performed at 130° C. and the second baking was performed at 500° C. for 1 hour. The obtained, baked material of titanium oxide was dipped in a 40 mM TiCl₄ aqueous solution, and then heated for 1 hour at 60° C. Next, the resulting material was heated for 30 minutes at 500° C., and thus a porous layer 12 (thickness: 500 nm) formed of TiO₂ was formed.

<Formation of Photosensitive Layer 13A>

On the porous layer 12 formed as described above, one of the following photosensitive layers A to C was formed as follows to produce a first electrode 1.

(Formation of Photosensitive Layer A)

A 40% methanol solution of methylamine (27.86 mL) and an aqueous solution of 57 mass % of hydrogen iodide (hydriodic acid, 30 mL) were stirred for 2 hours at 0° C. in a flask, and then concentrated to obtain a crude material of CH₃NH₃I. The obtained crude material of CH₃NH₃I was dissolved in ethanol and recrystallized with diethyl ether. The precipitated crystals were filtered and dried under reduced pressure for 24 hours at 60° C., and thus purified CH₃NH₃I was obtained.

Next, the purified CH₃NH₃I and PbI₂ were stirred and mixed at a molar ratio of 2:1 for 12 hours at 60° C. in γ-butyrolactone, and then filtered by a polytetrafluoroethylene (PTFE) syringe filter to prepare a 40 mass % light absorber solution A.

The prepared light absorber solution A was applied to the porous layer 12 through a spin coating method (for 60 seconds at 2000 rpm, then for 60 seconds at 3000 rpm), and the applied light absorber solution A was dried using a hot plate for 40 minutes at 100° C. to form a photosensitive layer A (thickness: 600 nm) as a photosensitive layer 13A having a perovskite compound. The obtained perovskite compound was CH₃NH₃PbI₃.

(Formation of Photosensitive Layer B)

Formamidine acetate and an aqueous solution of 57 mass % of hydrogen iodide, containing the hydrogen iodide 2 eq. based on the formamidine acetate, were stirred for 1 hour at 0° C. in a flask, and then further stirred and mixed for 1 hour after the temperature was raised to 50° C. The obtained solution was concentrated to obtain a crude material of formamidine-hydrogen iodate. The obtained crude material was recrystallized with diethyl ether, and the precipitated crystals were filtered and dried under reduced pressure for 10 hours at 50° C. Thus, purified formamidine-hydrogen iodate was obtained.

Next, the purified formamidine-hydrogen iodate and PbI₂ were stirred and mixed at a molar ratio of 2:1 for 3 hours at 60° C. in dimethylformamide (DMF), and then filtered by a polytetrafluoroethylene (PTFE) syringe filter to prepare a 40 mass % light absorber solution B.

The prepared light absorber solution B was applied to the porous layer 12 through a spin coating method (for 60 seconds at 2000 rpm, then for 60 seconds at 3000 rpm). The applied light absorber solution B was dried using a hot plate for 40 minutes at 160° C. to form a photosensitive layer B as a photosensitive layer 13A having a perovskite compound. The obtained perovskite compound was CH(═NH)NH₃PbI₃.

(Formation of Photosensitive Layer C)

A 40% ethanol solution of ethylamine and an aqueous solution of 57 mass % of hydrogen iodide were stirred for 2 hours at 0° C. in a flask, and then concentrated to obtain a crude material of CH₃CH₂NH₃I. The obtained crude material was dissolved in ethanol and recrystallized with diethyl ether. The precipitated crystals were filtered and dried under reduced pressure for 12 hours at 60° C., and thus purified CH₃CH₂NH₃I was obtained.

Next, the purified CH₃CH₂NH₃I and PbI₂ were stirred and mixed at a molar ratio of 3:1 for 5 hours at 60° C. in dimethylformamide (DMF), and then filtered by a polytetrafluoroethylene (PTFE) syringe filter to prepare a 40 mass % light absorber solution C.

The prepared light absorber solution C was applied to the porous layer 12 through a spin coating method (for 60 seconds at 2000 rpm, then for 60 seconds at 3000 rpm). The applied light absorber solution C was dried using a hot plate for 40 minutes at 140° C. to form a photosensitive layer C as a photosensitive layer 13A having a perovskite compound. The obtained perovskite compound was (CH₃CH₂—NH₃)₂PbI₄.

<Preparation of Hole Transport Material Solution>

A hole transport material (180 mg) described in the following Table 1 was dissolved in chlorobenzene (1 mL). To this chlorobenzene solution, an acetonitrile solution (37.5 μL) prepared by dissolving lithium-bis(trifluoromethane sulfonyl)imide (170 mg) in acetonitrile (1 mL) and t-butylpyridine (TBP, 17.5 μL) were added and mixed, and thus a hole transport material solution was prepared.

<Formation of Hole Transport Layer 3>

Next, the prepared hole transport material solution was applied to the photosensitive layer 13 of the first electrode 1 through a spin coating method, and the applied hole transport material solution was dried to form a hole transport layer 3 (thickness: 0.5 μm).

<Production of Second Electrode 2>

A second electrode 2 (thickness: 0.3 μm) was produced by depositing gold on the hole transport layer 3 through a deposition method.

Photoelectric conversion elements and solar cells (Sample Nos. 101 to 125, 201, and 202) were manufactured in the same manner, except that photosensitive layers and hole transport materials described in Table 1 were used.

Here, regarding the above-described thicknesses, the observation was performed using a SEM according to the above-described method, and an average of ten parts in the observation range was obtained and set as a thickness.

The following performance of the solar cells manufactured as described above was evaluated as follows.

The energy level of the HOMO of the hole transport material obtained by DFT calculation was calculated using B3LYP as a functional and 3-21 G as a basis function with Gaussian 09.

<Solar Cell Evaluation>

Using the solar cells manufactured as described above, a cell characteristic test was performed. Through this test, a short-circuit current density (Jsc: unit mA/cm²), an open circuit voltage (Voc: unit V), and a fill factor (FF) of each solar cell were obtained, and the cell output was divided by incident energy to calculate photoelectric conversion efficiency [η (%)].

The cell characteristic test was performed using a solar simulator “PEC-L12” (manufactured by Peccell Technologies, Inc.). The performance evaluation was performed using an I-V characteristic measurement device “PECK2400-N” (manufactured by Peccell Technologies, Inc.).

(Initial Performance Evaluation)

The initial performance was evaluated with initial conversion efficiency. Specifically, for each sample No., five solar cells were manufactured under the same conditions, and the photoelectric conversion efficiency of the obtained five solar cells was calculated as described above to obtain an average thereof. The obtained average was set as the initial conversion efficiency of the solar cell of each sample No.

Using the initial conversion efficiency obtained as described above, the initial performance was evaluated based on the following evaluation standards.

In the invention, A, B+, and B are required in the initial performance evaluation, and A is preferred for practical use.

A: The initial conversion efficiency was 1.3 or more times the initial conversion efficiency of the following comparative compound R-2.

B+: The initial conversion efficiency was 1.2 to less than 1.3 times the initial conversion efficiency of the following comparative compound R-2.

B: The initial conversion efficiency was 1.1 to less than 1.2 times the initial conversion efficiency of the following comparative compound R-2.

C: The initial conversion efficiency was less than 1.1 times the initial conversion efficiency of the following comparative compound R-2.

(Evaluation of Variation in Initial Performance)

The variation in the initial performance was evaluated with the variation in the initial conversion efficiency. Specifically, for each sample No. of the solar cell, standard deviation of the initial conversion efficiency of five solar cells was obtained.

With the standard deviation value of the initial conversion efficiency obtained as described above, the variation in the initial performance was evaluated based on the following evaluation standards.

In the invention, A, B+, and B are required in the evaluation of the variation in the initial performance, and A is preferred for practical use.

A: The standard deviation value of the initial conversion efficiency was less than 0.1 times the standard deviation value of the initial conversion efficiency of the following comparative compound R-2.

B+: The standard deviation value of the initial conversion efficiency was 0.1 to less than 0.2 times the standard deviation value of the initial conversion efficiency of the following comparative compound R-2.

B: The standard deviation value of the initial conversion efficiency was 0.2 to less than 0.3 times the standard deviation value of the initial conversion efficiency of the following comparative compound R-2.

C: The standard deviation value of the initial conversion efficiency was 0.3 or more times the standard deviation value of the initial conversion efficiency of the following comparative compound R-2.

TABLE 1

| | | | Energy | | Variation | |
|---|---|---|---|---|---|---|
| Sam- | Photo- | Hole | Level of | Initial | in Initial | |
| ple | sensitive | Transport | HOMO | Perfor- | Perfor- | |
| No. | Layer | Material | (eV) | mance | mance | Remarks |
| 101 | A | B-1 | −4.94 | B+ | B | The |
| | | | | | | Invention |
| 102 | A | B-3 | −4.87 | B+ | B | The |
| | | | | | | Invention |
| 103 | A | B-4 | −4.66 | A | B | The |
| | | | | | | Invention |
| 104 | A | B-5 | −4.81 | B+ | B | The |
| | | | | | | Invention |
| 105 | A | B-6 | −4.78 | A | B | The |
| | | | | | | Invention |
| 106 | A | B-8 | −4.74 | A | B | The |
| | | | | | | Invention |
| 107 | A | F4 | −4.62 | A | A | The |
| | | | | | | Invention |
| 108 | A | F6 | −4.67 | A | A | The |
| | | | | | | Invention |
| 109 | A | F9 | −4.71 | A | A | The |
| | | | | | | Invention |
| 110 | A | F18 | −4.77 | A | A | The |
| | | | | | | Invention |
| 111 | A | F19 | −4.61 | A | A | The |
| | | | | | | Invention |
| 112 | A | F21 | −4.75 | A | A | The |
| | | | | | | Invention |
| 113 | A | F22 | −4.74 | A | A | The |
| | | | | | | Invention |
| 114 | A | F25 | −4.50 | B+ | A | The |
| | | | | | | Invention |
| 115 | A | F27 | −4.52 | B+ | A | The |
| | | | | | | Invention |
| 116 | B | B-1 | −4.94 | B+ | B | The |
| | | | | | | Invention |
| 117 | C | B-1 | −4.94 | B+ | B | The |
| | | | | | | Invention |
| 118 | A | B-11 | −4.54 | B | B | The |
| | | | | | | Invention |
| 119 | A | B-12 | −4.56 | B | B | The |
| | | | | | | Invention |
| 120 | A | B-13 | −4.56 | B | B | The |
| | | | | | | Invention |
| 121 | A | B-14 | −4.53 | B | B | The |
| | | | | | | Invention |
| 122 | A | B-15 | −4.57 | B | B | The |
| | | | | | | Invention |
| 123 | A | B-16 | −4.54 | B+ | B | The |
| | | | | | | Invention |
| 124 | A | B-17 | −4.55 | B+ | B | The |
| | | | | | | Invention |
| 125 | A | B-18 | −4.64 | A | B | The |
| | | | | | | Invention |
| 201 | A | R-1 | −5.08 | C | C | Compar- |
| | | | | | | ative |
| | | | | | | Example |
| 202 | A | R-2 | −4.46 | C | C | Compar- |
| | | | | | | ative |
| | | | | | | Example |

The hole transport materials used as the Sample Nos. 201 and 202 are compounds having the following structures.

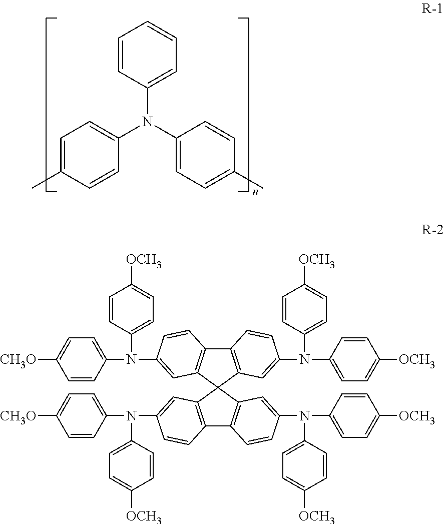

As is obvious from the results of Table 1, all of the solar cells of Sample Nos. 101 to 125 are found to have high photoelectric conversion efficiency and to have less variation in the performance in the manufacturing.

It is probable that in the solar cells provided with a photosensitive layer containing a perovskite compound as a light absorber, it was possible to increase the open voltage (Voc) as much as possible by forming a hole transport layer using a hole transport material of which the energy level of the HOMO obtained by the DFT calculation was within a range of −4.50 eV to −5.00 e. As a result, the solar cell of the invention has improved photoelectric conversion efficiency, and even when it is repeatedly manufactured, the variation in the cell performance is small, and thus stable cell performance is exhibited.

In addition, the effect of improving the photoelectric conversion efficiency is found to be further increased when using a hole transport material of which the energy level of the HOMO is within a range of −4.60 eV to −4.80 eV (Sample Nos. 103, 105 to 113, and 125). The effect of improving the photoelectric conversion efficiency is found to be further increased when Ar^{D1} of Formula (D) has a substituent T^{D2} (Sample Nos. 101 to 109, 111 to 117, and 123 to 125). Particularly, the effect of improving the photoelectric conversion efficiency is found to be further increased when the energy level of the HOMO is within a range of −4.60 eV to −4.80 eV and Ar^{D1} of Formula (D) has a substituent T^{D2} (Sample Nos. 103, 105 to 109, 111 to 113, and 125). The effect of suppressing the variation in the initial performance is found to be further increased when a hole transport material represented by Formula (L-2) is used as L^{D1} of Formula (D) (Sample Nos. 107 to 115).

The solar cell of the invention is found to have improved photoelectric conversion efficiency and to exhibit stable cell performance by using the above-described hole transport material together (Sample Nos. 101, 116, and 117), even when a compound represented by Formula (I-1) or a compound represented by Formula (I-2) is used as a light absorber.

### EXPLANATION OF REFERENCES

1A, 1B, 1C: first electrode
11: conductive support
11a: support
11b: transparent electrode
12: porous layer
13A, 13B, 13C: photosensitive layer
14: blocking layer
2: second electrode
3A, 3B, 3C: hole transport layer
6: external circuit (lead)
10A, 10B, 10C: photoelectric conversion element
100A, 100B, 100C: system in which photoelectric conversion element is applied for use in cell
M: electric motor

What is claimed is:

1. A photoelectric conversion element comprising:
a first electrode which has a photosensitive layer containing a light absorber on a conductive support;
a second electrode which is opposed to the first electrode; and
a hole transport layer which is provided between the first electrode and the second electrode,
wherein the light absorber includes a compound having a perovskite crystal structure having a cation of a group I element of the periodic table or a cation of a cationic organic group A, a cation of a metal atom M other than the group I elements of the periodic table, and an anion of an anionic atom X, and
the hole transport layer contains a hole transport material of which the energy level of the highest occupied molecular orbital obtained by density functional theory calculation is within a range of −4.50 eV to −5.00 eV.

2. The photoelectric conversion element according to claim 1,
wherein the hole transport material is represented by the following Formula (D), 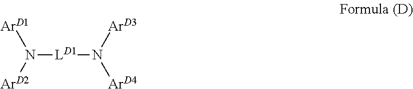
where L^{D1} indicates a linking group in which at least two of arylene groups and heteroarylene groups are combined, an arylene group, or a heteroarylene group, each of Ar^{D1} to Ar^{D4} independently indicates an aryl group or a heteroaryl group, Ar^{D1} to Ar^{D4} may have a substituent, Ar^{D1} and Ar^{D2} may be bonded to each other to form a ring, and Ar^{D3} and Ar^{D4} may be bonded to each other to form a ring.

3. The photoelectric conversion element according to claim 2,
wherein at least one of Ar^{D1} to Ar^{D4} has a substituent, and
the substituent is 1) an alkyl group, an alkoxy group, an alkylthio group, an alkylamino group, a dialkylamino group, an alkoxycarbonyl group, an alkylsilyl group, or an acyl group, which has two or more carbon atoms, or 2) an aryl group or a heteroaryl group substituted with the group described in 1).

4. The photoelectric conversion element according to claim 2,
wherein at least one of Ar^{D1} to Ar^{D4} has a substituent, and
the substituent is an alkyl group having two or more carbon atoms, an alkoxy group having two or more carbon atoms, an aryl group substituted with an alkyl group having two or more carbon atoms, an aryl group substituted with an alkoxy group having two or more carbon atoms, a heteroaryl group substituted with an alkyl group having two or more carbon atoms, or a heteroaryl group substituted with an alkoxy group having two or more carbon atoms.

5. The photoelectric conversion element according to claim 2,
wherein L^{D1} is represented by any one of the following Formulae (L-1) to (L-4), 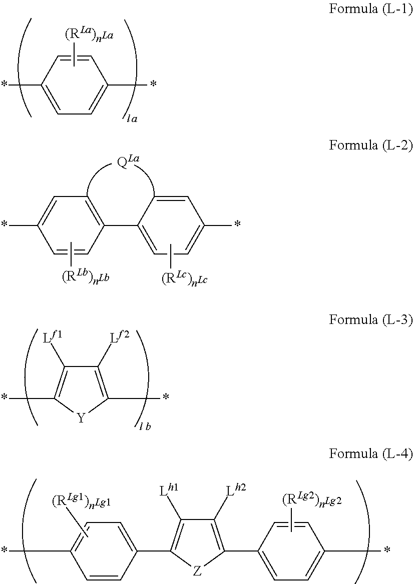
where each of Y and Z independently indicates O, S, or —CH═N—, each of R^{La} to R^{Lc}, R^{Lg1}, and R^{Lg2} independently indicates a substituent, each of R^{Lf1}, R^{Lf2}, R^{Lh1} and R^{Lh2} independently indicates a hydrogen atom or a substituent, each of n^{La}, n^{Lg1} and n^{Lg2} independently indicates an integer of 0 to 4, each of n^{Lb} and n^{Lc} independently indicates an integer of 0 to 3, each of la and lb independently indicates an integer of 1 to 4, Q^{La} indicates a group which forms a saturated hydrocarbon ring or a spiro ring of a five-membered ring or a six-membered ring, or —Si(Rx)(Ry)-, each of Rx and Ry independently indicates an alkyl group, and * indicates a bonding position with N of Formula (D).

6. The photoelectric conversion element according to claim 2,
wherein the hole transport material is represented by any one of the following 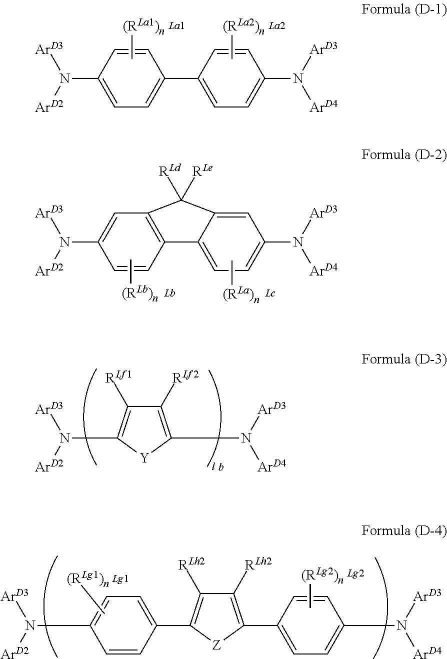
where each of Y and Z independently indicates O, S, or —CH═N—, lb indicates an integer of 1 to 4, Ar^{D1} to Ar^{D4} are synonymous with Ar^{D1} to Ar^{D4} of Formula (D), each of R^{La1}, R^{La2}, R^{Lb}, R^{Lc}, R^{Lg1}, and R^{Lg2} independently indicates a substituent, each of R^{Lf1}, R^{Lf2}, R^{Lh1}, and R^{Lh2} independently indicates a hydrogen atom or a substituent, each of n^{La1}, n^{La2}, n^{Lg1}, and n^{Lg2} independently indicates an integer of 0 to 4, each of n^{Lb} and n^{Lc} indicates an integer of 0 to 3, each of R^{Ld} and R^{Le} independently indicates an alkyl group, and R^{Ld} and R^{Le} may be bonded to each other to form a ring.

7. The photoelectric conversion element according to claim 2,
wherein Ar^{D1} is represented by any one of the following Formulae (R-1) to (R-3), 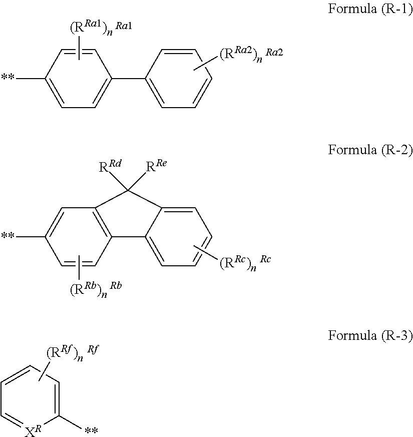
where X^{R} indicates CH or N, each of R^{Ra1}, R^{Ra2}, R^{Rb}, R^{Rc}, and R^{Rf} independently indicates a substituent, each of n^{Ra1}, n^{Rc}, and n^{Rf} independently indicates an integer of 0 to 4, n^{Ra2} indicates an integer of 0 to 5, n^{Rb} indicates an integer of 0 to 3, each of R^{Rd} and R^{Re} independently indicates an alkyl group, R^{Rd} and R^{Re} may be bonded to each other to form a ring, and ** indicates a bonding position with N in any one of Formulae (D).

8. The photoelectric conversion element according to claim 6,
wherein Ar^{D1} is represented by any one of the following Formulae (R-1) to (R-3), 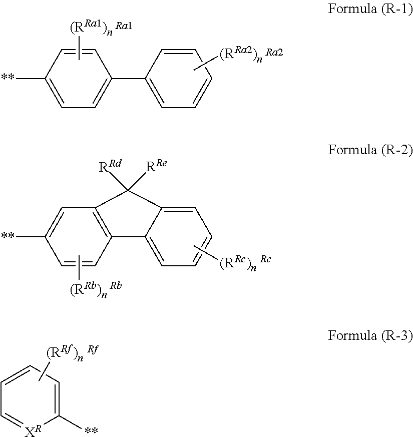
where X^{R} indicates CH or N, each of R^{Ra1}, R^{Ra2}, R^{Rb}, R^{Rc}, and R^{Rf} independently indicates a substituent, each of n^{Ra1}, n^{Rc}, and n^{Rf} independently indicates an integer of 0 to 4, n^{Ra2} indicates an integer of 0 to 5, n^{Rb} indicates an integer of 0 to 3, each of R^{Rd} and R^{Re} independently indicates an alkyl group, R^{Rd} and R^{Re} may be bonded to each other to form a ring, and ** indicates a bonding position with N in any one of Formulae (D).

9. The photoelectric conversion element according to claim 1,
wherein the energy level of the highest occupied molecular orbital is within a range of −4.60 eV to −4.80 eV.

10. The photoelectric conversion element according to claim 2,
wherein the energy level of the highest occupied molecular orbital is within a range of −4.60 eV to −4.80 eV.

11. The photoelectric conversion element according to claim 8,
wherein the energy level of the highest occupied molecular orbital is within a range of −4.60 eV to −4.80 eV.

12. The photoelectric conversion element according to claim 1,
wherein the compound having a perovskite crystal structure is a compound represented by the following Formula (I),
AₐMₘXₓ Formula (I):
where A indicates a group I element of the periodic table or a cationic organic group, M indicates a metal atom other than the group I elements of the periodic table, X indicates an anionic atom, a indicates 1 or 2, m indicates 1, and a, m, and x satisfy a+2m=x.

13. The photoelectric conversion element according to claim 1,
wherein the compound having a perovskite crystal structure includes a compound represented by the following Formula (I-1),
AMX₃ Formula (I-1):
where A indicates a group I element of the periodic table or a cationic organic group, M indicates a metal atom other than the group I elements of the periodic table, and X indicates an anionic atom.

14. The photoelectric conversion element according to claim 1,
wherein the compound having a perovskite crystal structure includes a compound represented by the following Formula (I-2),
A₂MX₄ Formula (I-2):
where A indicates a group I element of the periodic table or a cationic organic group, M indicates a metal atom other than the group I elements of the periodic table, and X indicates an anionic atom.

15. The photoelectric conversion element according to claim 1,
wherein A is represented by the following Formula (1),
R^{1a}—NH₃ Formula (1):
where R^{1a} indicates a substituent.

16. The photoelectric conversion element according to claim 15,
wherein R^{1a} is an alkyl group, a cycloalkyl group, an alkenyl group, an alkynyl group, an aryl group, a heteroaryl group, or a group represented by the following Formula (2), 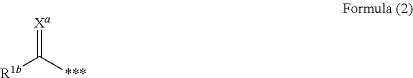
where X^{a} indicates NR^{1c}, an oxygen atom, or a sulfur atom, each of R^{1b} and R^{1c} independently indicates a hydrogen atom or a substituent, and *** indicates a bonding position with N of Formula (1).

17. The photoelectric conversion element according to claim 1,
wherein X is a halogen atom.

18. The photoelectric conversion element according to claim 1,
wherein M is Pb or Sn.

19. The photoelectric conversion element according to claim 1, further comprising:
a porous layer which is between the conductive support and the photosensitive layer.

20. A solar cell comprising:
the photoelectric conversion element according to claim 1.
